(19) United States
(12) Patent Application Publication
(10) Pub. No.: US 2011/0031552 A1
(43) Pub. Date: Feb. 10, 2011

(54) SEMICONDUCTOR DEVICE AND MANUFACTURING METHOD THEREOF

(75) Inventors: Toshiaki IWAMATSU, Kanagawa (JP); Kozo Ishikawa, Itami (JP); Kiyoshi Hayashi, Kanagawa (JP)

Correspondence Address: MCDERMOTT WILL & EMERY LLP, 600 13TH STREET, N.W., WASHINGTON, DC, 20005-3096, US

(73) Assignee: RENESAS ELECTRONICS CORPORATION

(21) Appl. No.: 12/852,039

(22) Filed: Aug. 6, 2010

(30) Foreign Application Priority Data
Aug. 7, 2009 (JP) 2009-184285

(51) Int. Cl. H01L 27/12; H01L 21/84

(52) U.S. Cl. 257/347; 438/154; 257/E21.704; 257/E27.112

(57) ABSTRACT

To provide, in FINFET whose threshold voltage is determined essentially by the work function of a gate electrode, a technology capable of adjusting the threshold voltage of FINFET without changing the material of the gate electrode. FINFET is formed over an SOI substrate comprised of a substrate layer, a buried insulating layer formed over the substrate layer, and a silicon layer formed over the buried insulating layer. The substrate layer has therein a first semiconductor region contiguous to the buried insulating layer. The silicon layer of the SOI substrate is processed into a fin. A ratio of the height of the fin to the width of the fin is adjusted to fall within a range of from 1 or greater but not greater than 2. In addition, a voltage can be applied to the first semiconductor region.

### CROSS-REFERENCE TO RELATED APPLICATIONS

The disclosure of Japanese Patent Application No. 2009-184285 filed on Aug. 7, 2009 including the specification, drawings and abstract is incorporated herein by reference in its entirety.

### BACKGROUND OF THE INVENTION

The present invention relates to a semiconductor device and a manufacturing technology thereof, in particular, to a semiconductor device having a FINFET (FIN field effect transistor) and a technology effective when applied to a manufacturing technology thereof.

Japanese Unexamined Patent Publication No. 2009-105122 (Patent Document 1) describes a technology for the purpose of providing a semiconductor device equipped with a FINFET excellent in characteristics by improving the processing accuracy of a fin or gate electrode forming the FINFET or improving the variation among a plurality of FINFETs. More specifically, it describes a semiconductor device obtained by forming a FINFET over an SOI (silicon on insulator) substrate and forming a gate electrode of this FINFET from a metal material or silicide material which can be wet-etched.

Japanese Unexamined Patent Publication No. 2009-135140 (Patent Document 2) describes a technology for the purpose of providing a technology capable of satisfying, in a semiconductor device having a thin film BOX (buried oxide)-SOI structure and having a logic circuit and a memory circuit over the same semiconductor substrate, both a high-speed operation in the logic circuit and a stable operation in the memory circuit. Described specifically, the semiconductor device described in Patent Document 2 has a thin film BOX-SOI structure. This semiconductor device is equipped with a transistor configuring the logic circuit and having a first gate electrode and another transistor configuring the memory circuit and having a second gate electrode. Below at least the first gate electrode, a triple well is formed in a supporting substrate configuring the thin-film BOX-SOI structure. This makes it possible to apply back biases of different polarities to the transistor configuring the logic circuit and the transistor configuring the memory circuit, respectively. In other words, a forward bias can be applied as the back bias of the former one and a reverse bias can be applied as the back bias of the latter one. This makes it possible to satisfy both the speed up of the logic circuit and operation stability of the memory circuit.

Japanese Unexamined Patent Publication No. 2006-12995 (Patent Document 3) describes a technology of using an SOI substrate having a BOX layer 200 nm or less thick. It also describes that a FINFET may be formed over the SOI substrate in this technology.

### [Patent Document 1] Japanese Unexamined Patent Publication No. 2009-105122

### [Patent Document 2] Japanese Unexamined Patent Publication No. 2009-135140

### [Patent Document 3] Japanese Unexamined Patent Publication No. 2006-12995

### SUMMARY OF THE INVENTION

In recent years, the dimension of a MISFET (metal insulator semiconductor field effect transistor) which is a configuring element of LSI (large scale integration) using silicon, particularly, the length of a gate electrode has been decreasing. This dimensional reduction in the MISFET has been performed in accordance with the scaling law, but various problems have appeared as the generation of a device becomes greater. It therefore becomes difficult to satisfy both the suppression of a short channel effect of a MISFET and securement of a high current driving power. Accordingly, research and development of a device having a novel structure instead of a conventional planar type (flat type) MISFET have been carried out briskly.

The FINFET is one of the above-described devices having a novel structure and it is a three-dimensional MISFET different from the planar type MISFET. In recent years, this FINEFT has attracted attentions as an important device candidate.

The FINFET has a fin formed by processing a semiconductor layer. This fin is a region in a thin strip form (in the form of a rectangular solid) and both side-surface portions of the fin are used as channels of the FINFET. The gate electrode of the FINFET is formed over the both side surface portions of the fin so as to straddle over the fin. It has a so-called double gate structure. The FINEFT having such a configuration is superior to the MISFET having a conventional single gate structure from the standpoint of potential control of the channel region by the gate electrode. The FINFET has therefore advantages such as high punch-through resistance between a source region and a drain region and suppression of a short-channel effect even at a smaller gate length. Since the FINFET uses the both side surface portions of the fin as a channel, an area of the channel region through which a current is caused to flow can be made greater and a higher current driving power can be attained. This means that the FINFET is expected to satisfy both the suppression of a short-channel effect and securement of a high current driving power.

The FINFET has however difficulty in controlling its threshold voltage. For example, in the conventional planar type MISFET, its threshold voltage is controlled by adjusting the impurity concentration in the channel region. In this case, as the planar type MISFET becomes smaller, the concentration of an impurity to be introduced into the channel region becomes higher in accordance with the scaling law. This means that in the conventional planar type MISFET, size reduction decreases the distance between the source region and the drain region, tending to cause punch-through. The punch-through is therefore controlled by raising the impurity concentration of the channel formed between the source and the drain. An increase in the impurity concentration of the channel however increases the variation in the impurity concentration among elements, resulting in an increase in the variation in the characteristics of the planar type MISFET. In addition, it enhances impurity scattering due to carriers passing through the channel, causing deterioration in the mobility of the carriers.

On the other hand, the FINFET is based on an operating principle similar to that of a fully depleted MISFET so that the impurity concentration in the channel can be reduced. It is expected as an element capable of reducing the variation in electrical characteristics among MISFETs due to a high impurity concentration. Described specifically, in the FINFET, the threshold voltage is controlled not by adjusting the concentration of an impurity to be introduced into the channel but by selecting a work function of the gate electrode appropriately. Accordingly, the threshold voltage of the FINFET is essentially determined by the work function of the gate electrode so that it is difficult to control the threshold voltage of the FINFET. In the FINFET, once a material of the gate electrode is determined, the threshold voltage is determined inevitably.

LSI has circuits having various functions and MISFETs configuring these circuits sometimes differ in threshold voltage. This means that the threshold voltage of a plurality of MISFETs formed in the same semiconductor substrate is sometimes made different from each other. In this case, when the FINFET is used, the material of the gate electrode should be changed in order to change the threshold voltage. Using the FINFET has therefore a problem that it complicates the manufacturing process of a semiconductor device or structure of the semiconductor device.

An object of the invention is to provide a technology capable of adjusting, in a FINFET whose threshold voltage is essentially determined by the work function of its gate electrode, the threshold voltage without changing the material of the gate electrode.

The above-described and other objects and novel features of the present invention will be apparent from the description herein and accompanying drawings.

Typical inventions, among the inventions disclosed in the present application, will next be described briefly.

A semiconductor device according to a typical mode is equipped with a first MISFET formed in a first region. The first MISFET has (a) an SOI substrate comprised of a substrate layer, a buried insulating layer formed over the substrate layer, and a semiconductor layer formed over the buried insulating layer and (b) a fin in a rectangular solid form having a long side in a first direction formed by processing the semiconductor layer. It has further (c) a first source region formed by processing the semiconductor layer and coupled to one end of the fin and (d) a first drain region formed by processing the semiconductor layer and coupled to another end of the fin. It has further (e) a first gate insulating film formed over the surface of the fin and (f) a first gate electrode straddling over the surface of the fin via the first gate insulating film in a region extending in a second direction intersecting with the first direction and at the same time intersecting with the fin. In this semiconductor device, a first semiconductor region having a conductivity type impurity introduced therein is formed in a portion of the substrate layer contiguous to the buried insulating layer and a ratio of the height of the fin to the width of the fin, which is a width in the second direction, is 1 or greater but not greater than 2.

A manufacturing method of a semiconductor device according to a typical mode is equipped with (a) a step of preparing an SOI substrate comprised of a substrate layer, a buried insulating layer formed over the substrate layer, and a semiconductor layer formed over the buried insulating layer, (b) a step of introducing a conductivity type impurity into the substrate layer of the SOI substrate, thereby forming in the substrate layer a first semiconductor region contiguous to the buried insulating layer, and (c) a step of forming a first MISFET in a first region of the SOI substrate. In this mode, the step (c) is equipped with (c1) a step of processing the semiconductor layer of the SOI substrate to form a fin in a rectangular solid form having a long side in a first direction, a first source region to be coupled to one end of the fin, and a first drain region to be coupled to another end of the fin and (c2) a step of forming a first gate insulating film over the surface of the fin. It further has (c3) a step of forming, over the SOI substrate having the fin formed thereon, a first conductor film covering the fin therewith, (c4) processing the first conductor film to form a first gate electrode placed to straddle over the surface of the fin via the first gate insulating film in a region extending in a second direction intersecting with the first direction and at the same time intersecting with the fin. It further has (c5) a step of introducing a conductivity type impurity into the first source region and the first drain region. In this manufacturing method, a ratio of the height of the fin formed in the step (c) to the width of the fin, which is a width in the second direction, is 1 or greater but not greater than 2.

A manufacturing method of a semiconductor device according to another typical mode is a method of forming a first MISFET in a first region and a second MISFET in a second region. It is equipped with (a) a step of preparing an SOI substrate comprised of a substrate layer, a buried insulating layer formed over the substrate layer, and a semiconductor layer formed over the buried insulating layer, and (b) a step of removing the semiconductor layer and the buried insulating layer formed in the second region of the SOI substrate to expose the substrate layer. It is equipped further with (c) a step of introducing a conductivity type impurity into the substrate layer formed in the first region of the SOI substrate to form a first semiconductor region contiguous to the buried insulating layer in the substrate layer formed in the first region and (d) a step of forming the first MISFET in the first region and forming the second MISFET in the second region. In this manufacturing method, the step (d) has (d1) a step of, in the first region, processing the semiconductor layer of the SOI substrate to form a fin in a rectangular solid form having a long side in a first direction, a first source region to be coupled to one end of the fin, and a first drain region to be coupled to another end of the fin and (d2) a step of forming a first gate insulating film over the surface of the fin formed in the first region and forming a second gate insulating film over the substrate layer formed in the second region. It further has (d3) a step of forming a first conductor film to cover the fin formed over the SOI substrate in the first region, while forming the first conductor film over the second gate insulating film in the second region. It further has (d4) a step of processing the first conductor film formed in the first region to form a first gate electrode placed to straddle over the surface of the fin via the first gate insulating film in a region extending in a second direction intersecting with the first direction and at the same time intersecting with the fin, while processing the first conductor film formed in the second region to form a second gate electrode over the second gate insulating film. It has thereafter (d5) a step of introducing a conductivity type impurity into the first source region and the first drain region formed in the first region and (d6) a step of introducing a conductivity type impurity into the substrate layer formed in the second region to form a second source region and a second drain region. In this manufacturing method, a ratio of the height of the fin formed in the step (d1) to the width of the fin, which is a width in the second direction of the fin, is 1 or greater but not greater than 2.

Advantages available by typical inventions disclosed in the present application will next be described briefly.

In a FINFET whose threshold voltage is essentially determined by the work function of its electrode, the threshold voltage of the FINFET can be adjusted without changing the material of the gate electrode.

### BRIEF DESCRIPTION OF THE DRAWINGS

FIG. 1 is a diagram illustrating the layout structure of a semiconductor chip in Embodiment 1 of the invention;

FIG. 2 is a diagram illustrating the planar layout structure of a FINFET formed in an internal circuit region and a planar type MISFET formed in an I/O circuit region;

FIG. 3 is a cross-sectional view taken along a line A-A of FIG. 2;

FIG. 4 is a cross-sectional view taken along a line B-B of FIG. 2;

FIG. 5 is a perspective view illustrating the configuration of the appearance of the FINFET;

FIG. 6 is a cross-sectional view taken along a line C-C of FIG. 2;

FIG. 7 is a cross-sectional view taken along a line D-D of FIG. 2;

FIG. 8 is an enlarged cross-sectional view illustrating the configuration in the vicinity of a fin of the FINFET;

FIG. 9 is a graph showing a change in potential (voltage) in a buried insulating layer, a fin, and a gate insulating film when a back bias of from −1V to 1V is applied to a first semiconductor region of an n-channel FINFET having a fin form as illustrated in FIG. 8;

FIG. 10 is an enlarged cross-sectional view illustrating the configuration in the vicinity of a fin of the FINFET;

FIG. 11 is a graph showing a change in potential (voltage) in a buried insulating layer, a fin, and a gate insulating film when a back bias of from −1V to 1V is applied to a first semiconductor region of an n-channel FINFET having a fin form as illustrated in FIG. 10;

FIG. 12 is a cross-sectional view illustrating a manufacturing step of a semiconductor device according to Embodiment 1 of the invention;

FIG. 13 is a cross-sectional view illustrating a manufacturing step of the semiconductor device following that of FIG. 12;

FIG. 14 is a cross-sectional view illustrating a manufacturing step of the semiconductor device following that of FIG. 13;

FIG. 15 is a cross-sectional view illustrating a manufacturing step of the semiconductor device following that of FIG. 14;

FIG. 16 is a cross-sectional view illustrating a manufacturing step of the semiconductor device following that of FIG. 15;

FIG. 17 is a perspective view illustrating a manufacturing step of the semiconductor device following that of FIG. 16;

FIG. 18 is a perspective view illustrating a manufacturing step of the semiconductor device following that of FIG. 17;

FIG. 19 is a perspective view illustrating a manufacturing step of the semiconductor device following that of FIG. 18;

FIG. 20 is a perspective view illustrating a manufacturing step of the semiconductor device following that of FIG. 19;

FIG. 21 is a perspective view illustrating a manufacturing step of the semiconductor device following that of FIG. 20;

FIG. 22 is a perspective view illustrating a manufacturing step of the semiconductor device following that of FIG. 21;

FIG. 23 is a perspective view illustrating a manufacturing step of the semiconductor device following that of FIG. 22;

FIG. 24 is a perspective view illustrating a manufacturing step of the semiconductor device following that of FIG. 23;

FIG. 25 is a perspective view illustrating a manufacturing step of the semiconductor device following that of FIG. 24;

FIG. 26 is a perspective view illustrating a manufacturing step of the semiconductor device following that of FIG. 25;

FIG. 27 is a perspective view illustrating a manufacturing step of the semiconductor device following that of FIG. 26;

FIG. 28 is a perspective view illustrating a manufacturing step of the semiconductor device following that of FIG. 27;

FIG. 29 is a perspective view illustrating a manufacturing step of the semiconductor device following that of FIG. 28;

FIG. 30 is a perspective view illustrating a manufacturing step of the semiconductor device following that of FIG. 29;

FIG. 31 is a perspective view illustrating a manufacturing step of the semiconductor device following that of FIG. 30;

FIG. 32 is a perspective view illustrating a manufacturing step of the semiconductor device following that of FIG. 31;

FIG. 33 is a perspective view illustrating a manufacturing step of the semiconductor device following that of FIG. 32;

FIG. 34 is a graph showing the relationship between a dosage of an impurity implanted into the fin and sheet resistance of the fin in Embodiment 2;

FIG. 35 is a view illustrating an impurity diffusion region formed in the fin when an ion is implanted into the fin at a high energy;

FIG. 36 is a view illustrating an impurity diffusion region formed in the fin when an ion is implanted into the fin at a low energy;

FIG. 37 is a view illustrating the mechanism of gas cluster ion beam; and

FIG. 38 is another view illustrating the mechanism of gas cluster ion beam.

### DETAILED DESCRIPTION OF THE INVENTION

In the below-described embodiments, a description will be made after divided in plural sections or in plural embodiments if necessary for convenience's sake. These plural sections or embodiments are not independent each other, but in a relation such that one is a modification example, details, or complementary description of a part or whole of the other one unless otherwise specifically indicated.

In the below-described embodiments, when a reference is made to the number of elements (including the number, value, amount, and range), the number of elements is not limited to a specific number but can be greater than or less than the specific number unless otherwise specifically indicated or principally apparent that the number is limited to the specific number.

Moreover in the below-described embodiments, it is needless to say that the constituent elements (including element steps) are not always essential unless otherwise specifically indicated or principally apparent that they are essential.

Similarly, in the below-described embodiments, when a reference is made to the shape, positional relationship, or the like of the constituent elements, that substantially analogous or similar to it is also embraced unless otherwise specifically indicated or different in principle. This also applies to the above-described value and range.

In all the drawings for describing the below-described embodiments, the same members will be identified by like reference numerals and overlapping descriptions will be omitted. Incidentally, some plan views may be hatched to facilitate viewing of them.

### Embodiment 1

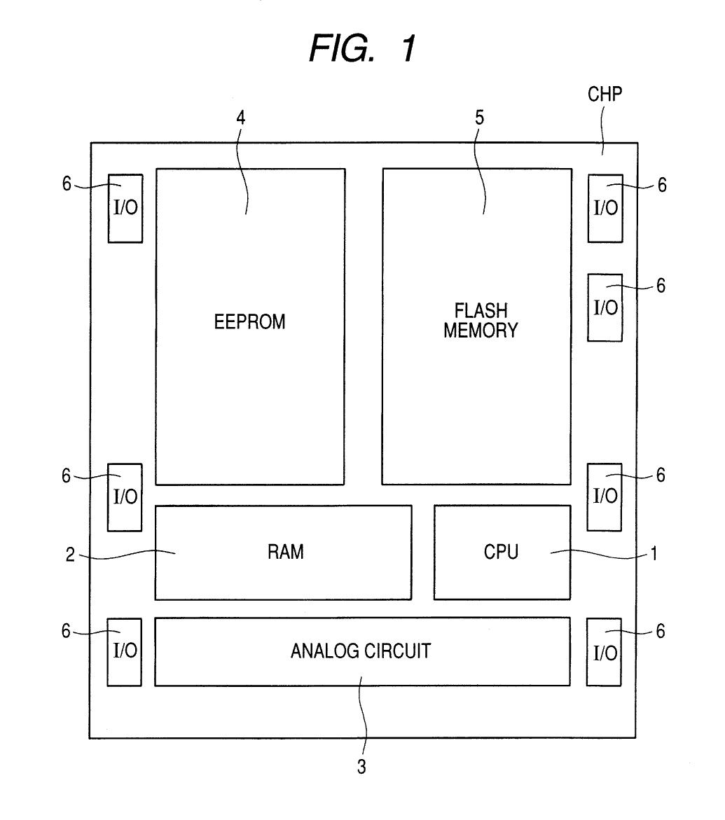

A semiconductor device according to Embodiment 1 will next be described referring to some drawings. First, the layout structure of a semiconductor chip having a system including a microcomputer will be described. FIG. 1 is a diagram illustrating the layout structure of a semiconductor chip CHP according to Embodiment 1. In FIG. 1, the semiconductor chip CHP has a CPU (central processing unit) 1, a RAM (random access memory) 2, an analog circuit 3, an EEPROM (electrically erasable programmable read only memory) 4, a flash memory 5, and an I/O (input/output) circuit 6.

The CPU (circuit) 1 is also called a central processing unit and is the heart of a computer or the like. The CPU1 fetches and decodes instructions from a memory device and based on them, it controls various operations or carries out a variety of arithmetic operations.

The RAM (circuit) 2 is a read/write memory. Stored information can be read randomly or written newly. It is also called a random access memory. There are two types of RAMs as an IC memory, that is, a DRAM (dynamic RAM) using a dynamic circuit and a SRAM (static RAM) having a static circuit. The DRAM is a random access memory that requires a memory retaining operation, while the SRAM is a random access memory that does not require a memory retaining operation. In the present embodiment 1, RAM2 is comprised of this SRAM.

The analog circuit 3 is a circuit treating signals such as voltage and current continuously changing with time, that is, analog signals. It is comprised of, for example, an amplifier circuit, a converter circuit, a modulator circuit, an oscillator circuit, and a power supply circuit.

The EEPROM 4 or the flash memory 5 is one of nonvolatile memories capable of electrically rewriting both a writing operation and an erasing operation and is also called an electrically erasable programmable read only memory. The memory cell of the EEPROM 4 or the flash memory 5 is comprised of, for example, a MONOS (metal oxide nitride oxide semiconductor) type transistor or a MNOS (metal nitride oxide semiconductor) type transistor for memory. The EEPROM 4 or the flash memory 5 utilizes, for the writing operation or erasing operation thereof, for example, Fowler-Nordheim tunneling. The writing operation or erasing operation can also be performed by making use of hot electrons or hot holes. A difference between the EEPROM 4 and the flash memory 5 is that the EEPROM 4 is a nonvolatile memory capable of erasing one byte at a time, while the flash memory 5 is a nonvolatile memory capable of erasing one word line at a time. In general, the flash memory 5 stores therein programs for carrying out various processing operations in CPU 1, while the EEPROM 4 stores therein various data which are rewritten frequently.

The I/O circuit 6 is an input/output circuit and is a circuit for outputting data from the semiconductor chip CHP to outside apparatuses coupled thereto or for inputting data to the semiconductor chip CHP from outside apparatuses coupled thereto.

The semiconductor chip CHP of Embodiment 1 has the configuration as described above. The structure of a semiconductor element formed over the semiconductor chip CHP will next be described. In Embodiment 1, internal circuits such as CPU 1 and RAM 2 are comprised of a FINFET and the I/O circuit 6 is comprised of a planar type MISFET. This means that the semiconductor chip CHP of Embodiment 1 has thereon both the FINFET and the planar type MISFET. The configuration of each of the FINFET and the planar type MISFET formed over the semiconductor chip CHP will next be described.

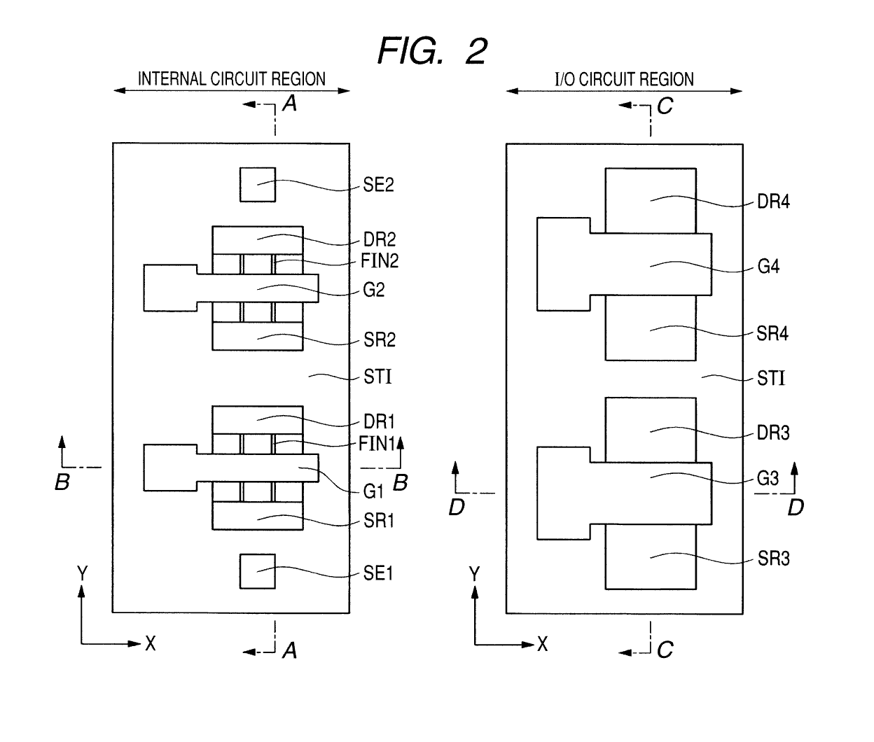

FIG. 2 is a diagram showing the planar layout of the FINFET formed in the internal circuit region and the planar type MISFET formed in the I/O circuit region. Referring to FIG. 2, the planar layout of the FINFET and the planar layout of the planar type MISFET will be described. First, the planar layout of the FINFET formed in the internal circuit region will be described. In FIG. 2, an element isolation region STI encompasses the internal circuit region and the FINFET is formed in active regions separated from each other by this element isolation region STI. FIG. 2 illustrates both an re-channel FINFET and a p-channel FINFET. The n-channel FINFET has, in the active region thereof encompassed with the element isolation region STI, a source region SR1 and a drain region DR1. The source region SR1 and the drain region DR1 have a fin FIN1 therebetween. In the n-channel FINFET, a fin FIN1 in a rectangular solid form having a long side in a direction Y is formed and this FIN1 is coupled, at one end thereof, to the source region SR1 and, at the other end, to the drain region DR1. Further, in the n-channel FINFET, a gate electrode G1 is formed so as to straddle over the surface of the fin FIN1 via a gate insulating film (not illustrated) in a region that extends in a direction X intersecting with the direction Y and at the same time, intersects with the fin FIN1. A region of the fin FIN1 covered with the gate electrode G1 functions as a channel region. In the n-channel FINFET having such a configuration, the source region SR1 and the drain region DR1 are each comprised of a semiconductor region having an n type impurity such as phosphorus (P) or arsenic (As) introduced therein and the fin FIN1 sandwiched between the source region SR1 and the drain region DR1 is also comprised of a semiconductor region. The gate electrode G1 is, on the other hand, made of, for example, a polysilicon film. Incidentally, the n-channel FINFET has, on the side thereof, a substrate electrode SE1.

The p-channel FINFET has a source region SR2 and a drain region DR2 in an active region encompassed with the element isolation region STI. The source region SR2 and the drain region DR2 have therebetween a fin FIN2. In the p-channel FINFET, the fin FIN2 in a rectangular solid form having a long side in a direction Y is formed and this fin FIN2 is coupled, at one end of the fin FIN2, to the source region SR2 and, at the other end of the fin FIN2, to the drain region DR2. Further, in the p-channel FINFET, a gate electrode G2 is formed in a region that extends in a direction X intersecting with the direction Y and at the same time, intersects with the fin FIN2, so as to stride over the surface of the fin FIN2 via a gate insulating film (not illustrated). A region of the fin FIN2 covered with the gate electrode G2 functions as a channel region. In the p-channel FINFET having such a configuration, the source region SR2 and the drain region DR2 are each comprised of a semiconductor region having a p type impurity such as boron (B) introduced therein and the fin FIN2 sandwiched between the source region SR2 and the drain region DR2 is also comprised of a semiconductor region. The gate electrode G2 is, on the other hand, made of, for example, a polysilicon film. Incidentally, the p-channel FINFET has, on the side thereof, a substrate electrode SE2. Thus, the re-channel FINFET and the p-channel FINFET are formed in the internal circuit region.

Next, the planar layout of the planar type MISFET formed in the I/O circuit region will be described. In FIG. 2, in the I/O circuit region, an element isolation region STI surrounds the periphery thereof and a planar type MISFET is formed in active regions separated with the element isolation region STI. FIG. 2 shows both an n-channel MISFET and a p-channel MISFET. The n-channel MISFET has a source region SR3 and a drain region DR3 in an active region encompassed with the element isolation region STI. The source region SR3 and the drain region DR3 have therebetween a channel region. A gate electrode G3 is formed over this channel region. The gate electrode G3 extends in a direction X. In the n-channel MISFET having such a configuration, the source region SR3 and the drain region DR3 are each comprised of a semiconductor region having an n type impurity such as phosphorus (P) or arsenic (As) introduced therein. On the other hand, the gate electrode G3 is formed, for example, of a polysilicon film.

Similarly, the p-channel MISFET has, in an active region encompassed with the element isolation region STI, a source region SR4 and a drain region DR4. The source region SR4 and the drain region DR4 have therebetween a channel region. A gate electrode G4 is formed over this channel region. The gate electrode G4 extends in a direction X. In the p-channel MISFET having such a configuration, the source region SR4 and the drain region DR4 are each comprised of a semiconductor region having a p type impurity such as boron (B) introduced therein. On the other hand, the gate electrode G4 is made of, for example, a polysilicon film.

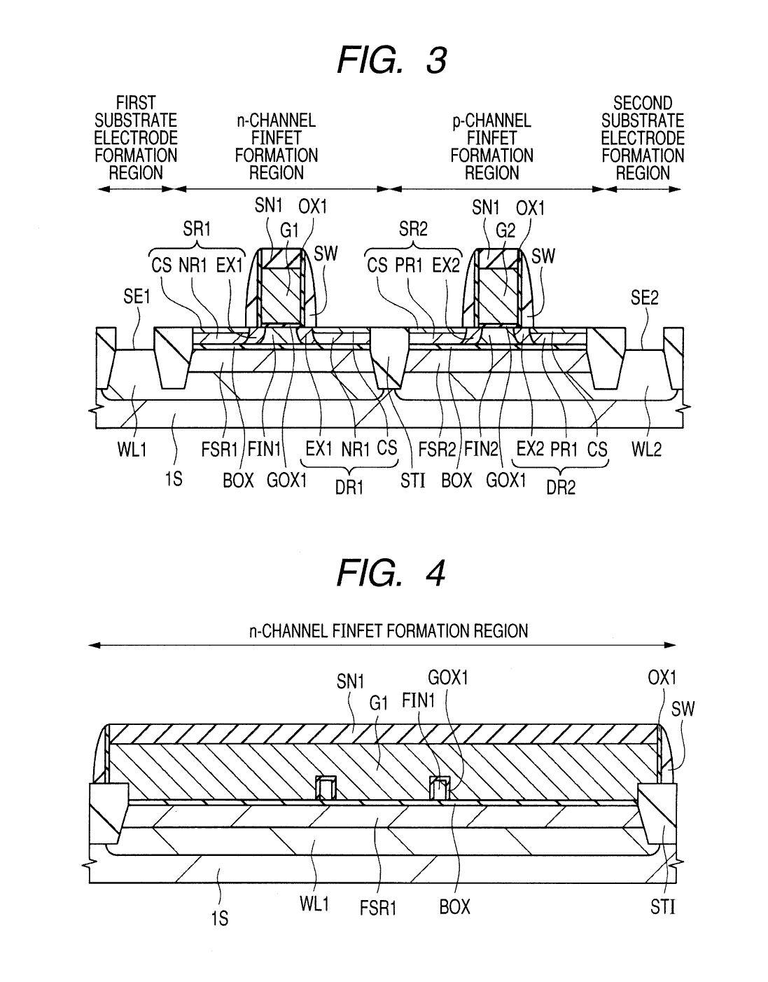

Next, the cross-sectional structure of the FINFET is described. FIG. 3 is a cross-sectional view taken along a line A-A of FIG. 2. In FIG. 3, the n-channel FINFET and the p-channel FINFET are formed over an SOI substrate. The SOI substrate is comprised of a substrate layer 1S comprised of silicon, a buried insulating layer BOX formed on the substrate layer 1S, and a silicon layer formed on the buried insulating layer BOX. The buried insulating layer BOX has a thickness of from about 10 nm to 20 nm. In the SOI substrate having such a configuration, the element isolation region STI is formed. In regions partitioned by the element isolation region STI, the n-channel FINFET and the p-channel FINFET are formed. A region formed on the left side of FIG. 3 corresponds to an n-channel FINFET formation region, while a region formed on the right side of FIG. 3 corresponds to a p-channel FINFET formation region. A first substrate electrode formation region is formed on the left side of the n-channel FINFET formation region, while a second substrate electrode formation region is formed on the right side of the p-channel FINFET formation region.

In FIG. 3, a well WL1 comprised of an n type semiconductor region is formed in the n-channel FINFET formation region and the first substrate electrode formation region in the substrate layer 1S. The surface of the well WL1 is exposed in the first substrate electrode formation region and this exposed region becomes a substrate electrode SE1. In the n-channel FINFET formation region, on the other hand, a first semiconductor region FSR1 is formed over the well WL1. This first semiconductor region FSR1 is a semiconductor region having an n type impurity introduced therein and is brought into contact with the buried insulating layer BOX. The concentration of an impurity introduced into the first semiconductor region FSR1 is higher than the concentration of an impurity introduced into the well WL1. This means that the impurity concentration in the first semiconductor region FSR1 is higher than the impurity concentration in the other regions of the substrate layer 1S (the substrate layer 1S itself and the well WL1). The well WL1 electrically couples the first semiconductor region FSR1 to the substrate electrode SE1 and enables application of a predetermined voltage to the first semiconductor region FSR1.

The first semiconductor region FSR1 has thereon a buried insulating layer BOX and this buried insulating layer BOX has thereon the fin FIN1. This means that the fin FIN1 is made of a silicon layer of the SOI substrate formed on the buried insulating layer BOX. The fin FIN1 has thereon a gate insulating film GOX1 and the gate insulating film GOX1 has thereon the gate electrode G1. The gate electrode G1 has thereon a silicon nitride film SN1 serving as a cap insulating film. The gate electrode G1 has, on the side wall on both surfaces thereof, a silicon oxide film OX1 and this silicon oxide film OX1 has, outside thereof, a sidewall SW. This means that the sidewall SW is formed over the side surfaces on both sides of the gate electrode G1 via the silicon oxide film OX1.

In the fin FIN1 formed below the gate electrode G1, a lightly-doped n-type impurity diffusion region EX1 is formed, while in the fin FIN1 outside of the lightly-doped n-type impurity diffusion region EX1, a heavily-doped n-type impurity diffusion region NR1 is formed. This heavily-doped n-type impurity diffusion region NR1 has, on the surface thereof, a cobalt silicide film CS. The lightly-doped n-type impurity diffusion region EX1, the heavily-doped n-type impurity diffusion region NR1, and the cobalt silicide film CS configure the source region SR1 and the drain region DR1. The cobalt silicide film CS is a film for reducing the sheet resistance of the source region SR1 and the drain region DR1. The cobalt silicide film CS may be replaced with a silicide film such as titanium silicide film, nickel silicide film, or platinum silicide film.

In FIG. 3, a well WL2 comprised of a p type semiconductor region is formed in the p-channel FINFET formation region and the second substrate electrode formation region in the substrate layer 1S. In the second substrate electrode formation region, the surface of the well WL2 is exposed and this exposed region becomes a substrate electrode SE2. In the p-channel FINFET formation region, on the other hand, a first semiconductor region FSR2 is formed on the well WL2. This first semiconductor region FSR2 is a semiconductor region having a p type impurity introduced therein and is brought into contact with the buried insulating layer BOX. The concentration of the impurity introduced into the first semiconductor region FSR2 is higher than the concentration of the impurity introduced into the well WL2. This means that the impurity concentration of the first semiconductor region FSR2 is higher than the impurity concentration of the other regions (the substrate layer 1S itself and the well WL2) of the substrate layer 1S. The well WL2 electrically couples the first semiconductor region FSR2 to the substrate electrode SE2 to apply a predetermined voltage to the first semiconductor region FSR2.

The first semiconductor region FSR2 has thereon a buried insulating layer BOX and this buried insulating layer BOX has thereon a fin FIN2. This means that the fin FIN2 is formed of a silicon layer of the SOI substrate formed on the buried insulating layer BOX. This fin FIN2 has thereon a gate insulating film GOX 1 and the gate insulating film GOX1 has thereon a gate electrode G2. This gate electrode G2 has thereon a silicon nitride film SN1 serving as a cap insulating film. The gate electrode G2 has, on the side surfaces on both sides thereof, a silicon oxide film OX1 and this silicon oxide film OX1 has, outside thereof, a sidewall SW. In short, the gate electrode G2 has, on the side surfaces on both sides thereof, a sidewall SW via the silicon oxide film OX1.

In the fin FIN2 formed below the gate electrode G2, a lightly-doped p-type impurity diffusion region EX2 is formed, while in the fin FIN2 outside of the lightly-doped p-type impurity diffusion region EX2, a heavily-doped p-type impurity diffusion region PR1 is formed. This heavily-doped p-type impurity diffusion region PR1 has, over the surface thereof, a cobalt silicide film CS. The lightly-doped p-type impurity diffusion region EX2, the heavily-doped p-type impurity diffusion region PR1, and the cobalt silicide film CS configure the source region SR2 and the drain region DR2. The cobalt silicide film CS is a film for reducing the sheet resistance of the source region SR2 and the drain region DR2. The cobalt silicide film CS may be replaced with a silicide film such as titanium silicide film, nickel silicide film, or platinum silicide film.

FIG. 4 is a cross-sectional view taken along a line B-B of FIG. 2. As illustrated in FIG. 4, the well WL1 which is an n type semiconductor region is formed in the substrate layer 1S and this well WL1 has thereon the first semiconductor region FSR1 which is an n type semiconductor region. This first semiconductor region FSR1 has thereon the buried insulating layer BOX and the buried insulating layer BOX has thereon the fin FIN1. The gate insulating film GOX 1 is formed so as to cover the surface of the fin FIN1 and the buried insulating layer BOX covering therewith the fin FIN1 has thereon the gate electrode G1. This gate electrode G1 has thereon the silicon nitride film SN1 and the gate electrode G1 has, on the side surfaces on both sides thereof, the sidewall SW via the silicon oxide film OX1.

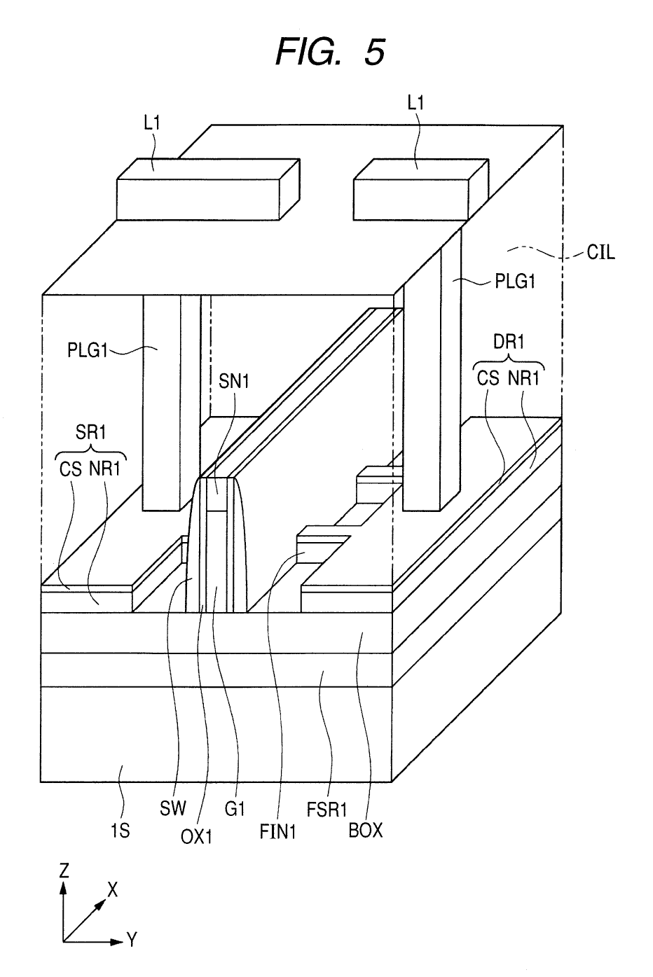

The planar structure of the FINFET is described above referring to FIG. 2 and the cross-sectional structure of the FINFET formed over the SOI substrate is described above referring to FIGS. 3 and 4. To facilitate understanding of the structure of the FINFET, the structure of the FINFET will next be described referring to some perspective views. FIG. 5 is a perspective view illustrating, for example, the configuration of the n-channel FINFET. In FIG. 5, a substrate layer 1S (well WL1) has thereon a first semiconductor region FSR1 and this first semiconductor region FSR1 has thereon a buried insulating layer BOX. This buried insulating layer BOX has thereon a source region SR1, a fin FIN1, and a drain region DR1. This means that in the SOI substrate, a silicon layer is formed on the buried insulating layer BOX. This silicon layer is processed into the source region SR1, the fin FIN1, and the drain region DR1. Described specifically, the fin FIN1 in a rectangular solid form having a long side in a direction Y is formed between the source region SR1 and the drain region DR1 and the fin FIN1 is coupled, at one end thereof, to the source region SR1 and coupled, at the other end of the fin FIN1, to the drain region DR1. The source region SR1 includes a heavily-doped n-type impurity diffusion region NR1 and a cobalt silicide film CS and the drain region DR1 also includes a heavily-doped n-type impurity diffusion region NR1 and a cobalt silicide film CS.

Further, in the n-channel FINFET, a gate electrode G1 straddling over the surface of the fin FIN1 is formed via a gate insulating film (not illustrated) in a region extending in a direction X intersecting with a direction Y and at the same time, intersecting with the fin FIN1. The region of the fin FIN1 covered with the gate electrode G1 functions as a channel region. In particular, the side surface of the fin FIN1 covered with the gate electrode G1 functions as a channel region. This means that the FINFET has a double gate structure in which both side surfaces of a rectangular solid configuring the fin FIN1 are used as a channel region. The gate electrode G1 has thereon a silicon nitride film SN1 serving as a cap insulating film. The gate electrode G1 has, on the side surfaces on both sides thereof, a sidewall SW via a silicon oxide film OX1. The fin FIN1 has two regions, that is, a region covered with the gate electrode G1 and a region not covered with the gate electrode G1 or the sidewall SW. The region covered with the gate electrode G1 becomes as a channel region and the region not covered with the gate electrode G1 or the sidewall SW becomes a portion of the source region SR1 or the drain region DR1. Described specifically, a lightly-doped n-type impurity diffusion region (not illustrated) is formed in the fin FIN1 in alignment with the gate electrode G1 and a heavily-doped n-type impurity diffusion region NR1 is formed in alignment with the sidewalls SW.

A contact interlayer insulating film CIL covers therewith the n-channel FINFET having such a configuration. A plug PLG1 to be coupled to the source region SR1 or the drain region DR1 of the n-channel FINFET penetrates through this contact interlayer insulating film CIL. An interconnect L1 is then formed on the contact interlayer insulating film CIL through which the PLG1 has been formed.

The cross-sectional structure of the planar type MISFET formed in the I/O circuit region will next be described. FIG. 6 is a cross-sectional view taken along a line C-C of FIG. 2. In FIG. 6, in the I/O circuit region, the n-channel FINFET and the p-channel FINFET are formed over the substrate layer 1S. Described specifically, from the SOI substrate comprised of the substrate layer 1S made of silicon, the buried insulating layer BOX formed on the substrate layer 1S, and a silicon layer formed on the buried insulating layer BOX, the silicon layer and the buried insulating layer BOX are removed and only the substrate layer 1S remains. In the substrate layer 1S having such a configuration, the element isolation region STI is formed. In regions partitioned with the element isolation region STI, the n-channel MISFET and the p-channel MISFET are formed. A region formed on the left side of FIG. 6 is the re-channel MISFET formation region and a region formed on the right side of FIG. 6 is the p-channel MISFET formation region.

First, the configuration of the n-channel MISFET formed in the n-channel MISFET formation region is described.

The substrate layer 1S has therein the element isolation region STI for separating elements from each other and in the n-channel MISFET formation, that is, one of active regions partitioned with the element isolation region STI, a well WL3 made of a p type semiconductor region is formed.

The n-channel MISFET has a gate insulating film GOX2 on the well WL3 formed in the substrate layer 1S and this gate insulating film GOX2 has thereon the gate electrode G3. The gate insulating film GOX2 is made of, for example, a silicon oxide film and the gate electrode G3 is made of, for example, a polysilicon film. The gate electrode G3 has thereon a silicon nitride film SN1 serving as a cap insulating film.

The gate electrode G3 has, on the side surfaces on both sides thereof, a sidewall SW via a silicon oxide film OX1 and a shallow n-type impurity diffusion region EX3 is formed as a semiconductor region in the substrate layer 1S below this sidewall SW. This sidewall SW is made of an insulating film such as a silicon oxide film. Outside the shallow n-type impurity diffusion region EX3, a deep n-type impurity diffusion region NR2 is formed and this deep n-type impurity diffusion region EX3 has, on the surface thereof, a cobalt silicide film CS.

The sidewall SW is formed in order to give an LDD structure to the source region and the drain region, which are semiconductor regions of the n-channel MISFET. Described specifically, the source region and the drain region in the re-channel MISFET are each comprised of the shallow n-type impurity diffusion region EX3 and the deep n-type impurity diffusion region NR2. The impurity concentration of the shallow n-type impurity diffusion region EX3 is lower than the impurity concentration of the deep n-type impurity diffusion region NR2. The electric field concentration below the end portions of the gate electrode G3 can be suppressed by forming the source region and drain region below the sidewall SW from the lightly-doped shallow n-type impurity diffusion region EX3.

The configuration of the p-channel MISFET formed in the p-channel MISFET formation region will next be described.

The element isolation region STI for separating elements from each other is formed in the substrate layer 1S and in the p-channel MISFET formation region, which is one of the active regions separated by the element isolation region STI, a well WL4 comprised of an n type semiconductor region is formed.

The p-channel MISFET has a gate insulating film GOX2 on the well WL4 formed in the substrate layer 1S and this gate insulating film GOX2 has thereon the gate electrode G4. The gate insulating film GOX2 is made of, for example, a silicon oxide film and the gate electrode G4 is made of, for example, a polysilicon film. The gate electrode G4 has thereon a silicon nitride film SN1 serving as a cap insulating film.

The gate electrode G4 has, on the side surfaces on both sides thereof, a sidewall SW via a silicon oxide film OX1 and in the substrate layer 1S below the sidewall SW, a shallow p-type impurity diffusion region EX4 is formed as a semiconductor region. The sidewall SW is made of an insulating film such as a silicon oxide film. The shallow p-type impurity diffusion region EX4 has, outside thereof, a deep p-type impurity diffusion region PR2 and this deep p-type impurity diffusion region PR2 has, on the surface thereof, a cobalt silicide film CS.

The sidewall SW is formed in order to give an LDD structure to the source region and the drain region, which are semiconductor regions of the p-channel MISFET. Described specifically, the source region and the drain region of the p-channel MISFET are each comprised of the shallow p-type impurity diffusion region EX4 and the deep p-type impurity diffusion region PR2. The impurity concentration of the shallow p-type impurity diffusion region EX4 is lower than the impurity concentration of the deep p-type impurity diffusion region PR2. The electric field concentration below the end portions of the gate electrode G4 can be suppressed by forming the source region and the drain region below the sidewall SW from the lightly-doped shallow p-type impurity diffusion region EX4.

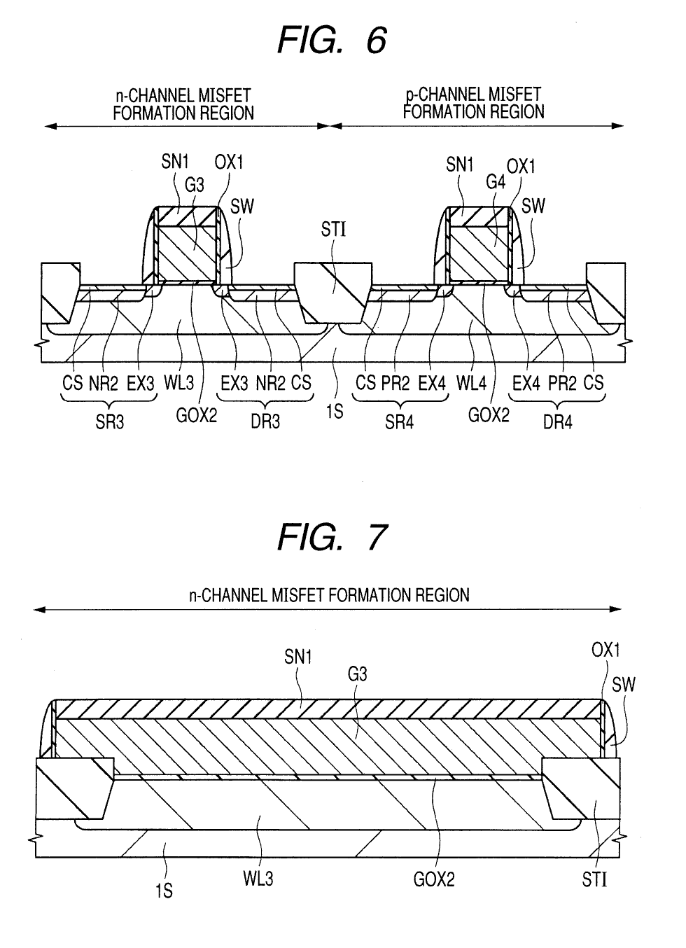

FIG. 7 is a cross-sectional view taken along a line D-D of FIG. 2. As illustrated in FIG. 7, the well WL3 which is a p type semiconductor region is formed in the substrate layer 1S and this well WL3 has thereon the gate insulating film GOX2. This gate insulating film GOX2 has thereon the gate electrode G3 and this gate electrode G3 has thereon the silicon nitride film SN1. Further, the gate electrode G3 has, on the side surfaces on both sides thereof, the sidewall SW via the silicon oxide film OX1. Thus, the FINFET is formed in the internal circuit region, while the planar type MISFET is formed in the I/O circuit region.

In Embodiment 1, semiconductor elements of the internal circuit configuring CPU or SRAM are made of a FINFET. Advantages and disadvantages of the internal circuit comprised of the FINFET will next be described. With recent reduction in the size of semiconductor chips, the size of the MISFET formed over semiconductor chips, particularly the gate length of the gate electrode is being reduced. Reduction in the size of MISFET has been performed based on the scaling law. As the size of the MISFET becomes smaller, however, it becomes difficult to suppress the short channel effect of the MISFET and ensure a high current driving power simultaneously. There is therefore a demand for the development of a novel structure device usable instead of the conventional planar type MISFET.

The FINFET is one of the above-described novel structure devices and is a three-dimensional structure MISFET different from the planar type MISFET. The FINFET has, as described above, a fin formed by processing a semiconductor layer. This fin is a region in the form of a thin strip (rectangular solid) and both side surface portions of this fin are used as the channel of the FINFET. The gate electrode of the FINFET is formed over the both side surfaces of the fin in such a manner as to straddle over the fin. Thus, the FINFET has a so-called double gate structure. In the FINFET having such a configuration, compared with the conventional planar type MISFET, the potential controllability for the channel region by the gate electrode is improved. The FINFET has high punch-through resistance between the source region and the drain region and can control the short channel effect even the gate length is smaller. In the FINFET, the both side surfaces of the fin are used as a channel so that the area of the channel region through which a current flows can be enlarged and a high current driving power can be attained. In short, the FINFET is an advantageous device capable of suppressing a short channel effect and ensuring a high current driving power simultaneously. The FINFET is therefore suited for application to a logic circuit (CPU) or SRAM using a miniaturized MISFET.

Furthermore, in the conventional planar type MISFET, its threshold voltage is controlled by adjusting the impurity concentration in the channel region. In this case, with a size reduction of the planar type MISFET, the concentration of an impurity to be introduced into the channel region increases in accordance with the scaling law. Described specifically, in the conventional planar type MISFET, particularly a distance between the source region and the drain region decreases by the size reduction and punch-through is likely to occur so that the impurity concentration of the channel formed between the source region and the drain region is raised to suppress a punch-through. As the impurity concentration of the channel is increased, however, the variation of the impurity concentration between elements increases, which causes large variation in the characteristics of the planar type MISFET. In addition, impurity scattering due to carriers passing through the channel increases, which deteriorates mobility of carriers.

The MISFET becomes more minute particularly in a SRAM. When the planar type MISFET is used for the SRAM, the following problems may occur. With miniaturization of the semiconductor chip, the concentration of an impurity to be introduced into the channel region becomes higher. This means an increase in the variation among elements. For example, when the threshold voltage varies among elements, the SRAM required to have a uniform property when used in pairs may fail to work normally. A miniaturized planar type MISFET cannot therefore be used freely for the SRAM.

It is presumed, on the other hand, that since the FINFET works based on a principle similar to that of a fully depleted MISFET, the impurity concentration in the channel can be decreased and the variation in electrical characteristics of MISFETs due to a high impurity concentration can be reduced. This means that the threshold voltage of the FINFET is controlled not by adjusting the concentration of an impurity to be introduced into the channel but properly selecting the work function of the gate electrode. In the FINFET, the concentration of an impurity to be introduced into the channel region (fin) can be reduced so that the variation in electrical characteristics due to an increased concentration of an impurity introduced into the channel region can be suppressed. The FINFET is therefore particularly suited for use in SRAM. Thus, compared with the planar type MISFET, the FINFET is advantageous because it can suppress a short channel effect and ensure a high current driving power and moreover, it seems possible to promote the application of it to minute semiconductor elements because an impurity concentration in the channel region can be reduced even in such elements.

The FINFET however works based on a principle similar to that of a fully depleted MISFET so that its threshold voltage is controlled not by adjusting the concentration of an impurity to be introduced into a channel but by properly selecting the work function of the gate electrode. The threshold value of the FINFET is therefore determined essentially by the work function of the gate electrode. It therefore becomes difficult to adjust the threshold voltage of the FINFET. In other words, the threshold voltage of the FINFET is inevitably determined once a material of the gate electrode is determined.

For example, circuits having a variety of functions are formed in internal circuits including, for example, CPU and SRAM and MISFETS configuring each circuit may sometimes differ in threshold voltage. In other words, the threshold voltage is sometimes made different among the plural MISFETs formed in the same semiconductor substrate. In this case, when a FINFET is used as a semiconductor element, a material of the gate electrode should be changed in order to change the threshold voltage. This may lead to the problem that the manufacturing process of a semiconductor device or the structure of a semiconductor device becomes complicated.

In Embodiment 1, a measure for adjusting the threshold voltage of the FINFET without changing the material of its gate electrode is taken in the FINFET whose threshold voltage is determined essentially by the work function of the gate electrode. The measure in Embodiment 1 will next be described.

First, the characteristic points in Embodiment 1 will be described referring to FIG. 3. In FIG. 3, an attention is paid to the n-channel FINFET formed in the n-channel FINFET formation region. Embodiment 1 is characterized by that the first semiconductor region FSR1 is formed in the substrate layer 1S of the SOI substrate. This first semiconductor region FSR1 is coupled to the substrate electrode SE1 via the well WL1 formed in the substrate layer 1S. A predetermined voltage applied to the substrate electrode SE1 is applied to the first semiconductor region FSR1. This means that when the predetermined voltage is applied to the substrate electrode SE1, it is applied to the first semiconductor region FSR1 coupled electrically to the substrate electrode SE1.

The first semiconductor region FSR1 has thereon the buried insulating layer BOX and this buried insulating layer BOX has thereon the fin FIN1. When a predetermined voltage is applied to the first semiconductor region FSR1, the voltage is applied to the surface of the fin FIN1 based on the relationship of a band between the first semiconductor region FSR1 and the fin FIN1 which is a semiconductor layer. This means that the gate insulating film GOX1 is formed on the surface of the fin FIN1 and the voltage is applied to the interface between the fin FIN1 and this gate insulating film GOX1. As a result, the threshold voltage of the n-channel FINFET is determined, depending on the voltage applied to the surface of the fin FIN1.

For example, when no impurity is introduced into the first semiconductor region FSR1, the first semiconductor region FSR1 becomes an intrinsic semiconductor region and a Fermi level lies near the center of a forbidden band. A voltage to be applied to the surface of the fin FIN1 is determined depending on the position of the Fermi level of the first semiconductor region FSR1. For example, a voltage to be applied to the surface of the fin FIN1 is designated as a first voltage. When an n type impurity is introduced into the first semiconductor region FSR1, on the other hand, the Fermi level of the first semiconductor region FSR1 shifts to the side of a conduction band. As a result, the voltage applied to the surface of the fin FIN1 changes into a second voltage due to shifting of the Fermi level of the first semiconductor region FSR1. Such a change of a voltage applied to the surface of the fin FIN1 from the first voltage to the second voltage means a change in the threshold voltage of the n-channel FINFET. This means that as in Embodiment 1, a voltage to be applied to the surface of the fin FIN1 can be changed by forming the first semiconductor region FSR1 in a portion of the substrate layer 1S contiguous to the buried insulating layer BOX and changing the concentration of an impurity to be introduced into this first semiconductor region FSR1. As a result, the threshold voltage of the n-channel FINFET can be changed. This means that the threshold voltage of a plurality of n-channel FINFETs can be changed by changing the concentration of an impurity to be introduced into the first semiconductor region FSR1 in a plurality of n-channel FINFETs which need a change in threshold voltage. In other words, even if the same voltage is applied from the substrate electrode SE 1, the threshold voltage differs when the concentration of an impurity introduced into the first semiconductor region is different. This means that the threshold voltage of the re-channel FINFET can be adjusted by changing the concentration of an impurity to be introduced into the first semiconductor region FSR1. Embodiment 1 is therefore characterized by that the threshold voltage of the n-channel FINFET can be adjusted by forming, in the substrate layer 1S, the first semiconductor region FSR1, which is an n type semiconductor region, contiguous to the buried insulating layer BOX and adjusting the concentration of an n type impurity to be controlled into this first semiconductor region FSR1. At this time, the concentration of an impurity to be introduced into the first semiconductor region FSR1 is higher than the concentration of an impurity to be introduced into the channel region in the fin FIN1.

The second characteristic in Embodiment 1 will next be described. The second characteristic in Embodiment 1 resides in changing a voltage to be applied to the first semiconductor region FSR1. A change in a voltage to be applied to the first semiconductor region FSR1 causes a change in a voltage to be applied to the surface of the fin FIN1. As a result, the threshold value of the n-channel FINFET can be changed by changing a voltage to be applied to the first semiconductor region FSR1. For example, the first semiconductor region FSR1 is coupled to the substrate electrode SE1 via the well WL1 so that a voltage to be applied to the first semiconductor region FSR1 can be changed by adjusting a voltage to be applied to the substrate electrode SE1. As a result, a voltage to be applied to the surface of the fin FIN1 changes, making it possible to adjust the threshold voltage of the n-channel FINFET. More specifically, the voltage to be applied to the first semiconductor region FSR1 can be adjusted to fall within a range of a supply voltage. For example, when a voltage higher than the supply voltage is applied to the first semiconductor region FSR1, a booster circuit or the like must be formed. By adjusting the voltage to be applied to the first semiconductor region FSR1 to fall within a range of a supply voltage, the booster circuit is not necessary, which simplifies the configuration. For example, assuming that a positive powers supply voltage is set at 1V and a negative supply voltage is set at −1V, a voltage to be applied to the first semiconductor region FSR1 falls within a range of from −1V to 1V.

Thus, the technical concept in Embodiment 1 has two characteristics as described above. The first characteristic is forming, in the substrate layer 1S, a first semiconductor region FSR1 contiguous to the buried insulating layer BOX and adjusting the concentration of an impurity to be introduced into this first semiconductor region FSR1 and the second characteristic is adjusting a voltage to be applied to the first semiconductor region FSR1. As a result, in the n-channel FINFET whose threshold voltage is determined essentially by a work function of the gate electrode, the threshold voltage of the n-channel FINFET can be adjusted without changing the material of the gate electrode. Further, in Embodiment 1, the concentration of an impurity to be introduced into the channel region in the fin FIN1 can be kept low, the variation in electrical characteristics due to an increased concentration of an impurity introduced into the channel region can be suppressed.

The above description is made, paying attention to the re-channel FINFET, but it also applies to the p-channel FINFET. Described specifically, as illustrated in FIG. 3, the threshold voltage of the p-channel FINFET can be adjusted by forming, in the substrate layer 1S, a first semiconductor region FSR2, which is a p type semiconductor region, contiguous to the buried insulating layer BOX and adjusting the concentration of a p type impurity to be introduced into this first semiconductor region FSR2. The concentration of an impurity to be introduced into the first semiconductor region FSR2 is higher than the concentration of an impurity to be introduced into the channel region in the fin FIN2.

Also in the p-channel FINFET, the threshold value of the p-channel FINFET can be changed by changing a voltage to be applied to the first semiconductor region FSR2. For example, since the first semiconductor region FSR2 is coupled to the substrate electrode SE2 via the well WL2, a voltage to be applied to the first semiconductor region FSR2 can be changed by adjusting a voltage to be applied to the substrate electrode SE2. As a result, a voltage to be applied to the surface of the fin FIN2 changes, making it possible to adjust the threshold voltage of the p-channel FINFET. More specifically, the voltage to be applied to the first semiconductor region FSR2 can be adjusted to fall within a supply voltage. For example, assuming that a positive supply voltage is set at 1V and a negative supply voltage is set at −1V, the voltage to be applied to the first semiconductor region FSR2 falls within a range of from −1V to 1V.

In Embodiment 1, when an attention is paid to the re-channel FINFET illustrated in FIG. 3, it has the following two characteristics: a first one is forming, in the substrate layer 1S, the first semiconductor region FSR1 contiguous to the buried insulating layer BOX and adjusting the concentration of an impurity to be introduced into this first semiconductor region FSR1 and a second one is adjusting a voltage to be applied to the first semiconductor region FSR1. It is however to be noted that the threshold voltage of the re-channel FINFET having both the first and second characteristics cannot always be adjusted. This means that whether the threshold voltage of the n-channel FINFET having both the first and second characteristics can be adjusted or not depends on the shape of the fin FIN1 in the n-channel FINFET. A description will next be made on this point referring to some drawings.

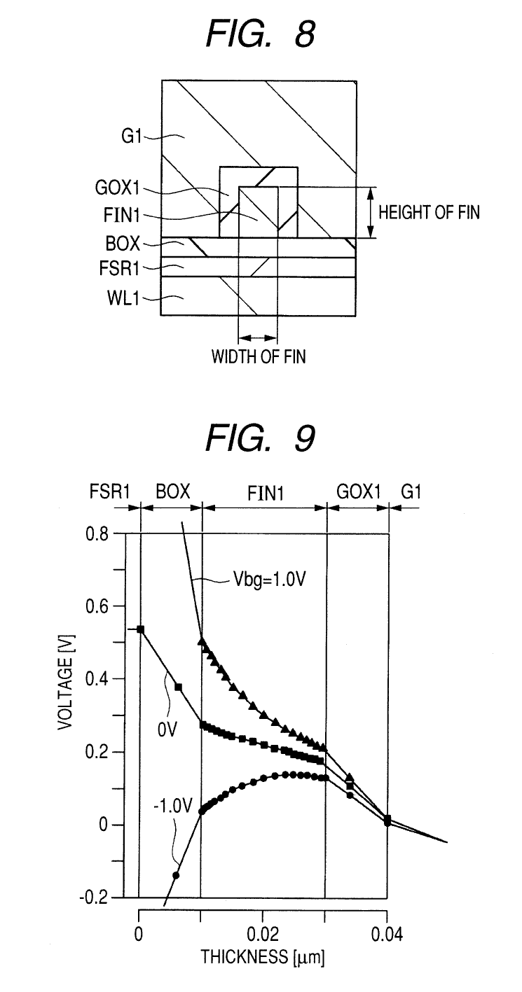

FIG. 8 is a cross-sectional view illustrating the structure in the vicinity of the fin FIN1. In FIG. 8, the well WL1 has thereon the first semiconductor region FSR1 and this first semiconductor region FSR1 has thereon the buried insulating layer BOX. The buried insulating layer BOX has thereon the fin FIN1 and this fin FIN1 has, on the surface thereof, the gate insulating film GOX1. The gate electrode G1 is formed so as to cover therewith the fin FIN1. The fin FIN1 has a width of about 15 nm and a height of about 20 nm. A change caused by application of a back bias Vbg of from −1V to 1V to the first semiconductor region FSR1 of the n-channel FINFET having such a configuration will next be considered.

FIG. 9 is a graph showing a change in the potential (voltage) in the buried insulating layer BOX, the fin FIN1, and the gate insulating film GOX1 when a back bias Vbg of from −1V to 1V is applied to the first semiconductor region FSR1 of the n-channel FINFET. In FIG. 9, a thickness (distance) (μm) from the upper surface of the first semiconductor region FSR1 is plotted along the abscissa and a voltage (potential) is plotted along the ordinate.

FIG. 9 includes graphs at a back bias Vbg of 0V, a back bias Vbg of −1V, and a back bias Vbg of 1V. First, the graph at a back bias Vbg of 0V will be described. In this case, the voltage at the interface between the first semiconductor region FSR1 and the buried insulating layer BOX is about 0.53V. The voltage decreases toward the interface between the buried insulating layer BOX and the fin FI1 at which it becomes 0.3V. Then, the voltage decreases mildly toward the interface between the fin FIN1 and the gate insulating film GOX1 (in other words, at the surface of the fin FIN1) at which it becomes about 0.19V.

Next, the graph at a back bias Vbg of −1V will be described. In this case, the voltage at the interface between the first semiconductor region FSR1 and the buried insulating layer BOX is too low and therefore not shown in the graph. The voltage increases toward the interface between the buried insulating layer BOX and the fin FIN1, at which it becomes about 0.05V. Then, the voltage increases mildly toward the interface between the fin FIN1 and the gate insulating film GOX1 (in other words, at the surface of the fin FIN1), at which it becomes about 0.1V.

Further, the graph at a back bias Vbg of 1V will be described. In this case, the voltage at the interface between the first semiconductor region FSR1 and the buried insulating layer BOX is too high and therefore not shown in the graph. The voltage decreases toward the interface between the buried insulating layer BOX and the fin FIN1, at which it becomes about 0.5V. Then, the voltage decreases mildly toward the interface between the fin FIN1 and the gate insulating film GOX1 (in other words, at the surface of the fin FIN1), at which it becomes about 0.21V.

From these three graphs, it has been found that a change in voltage occurs at the interface between the fin FIN1 and the gate insulating film GOX1. This means that in order to change a voltage to be applied to the first semiconductor region FSR1 from −1V to 1V, a voltage at the interface between the fin FIN1 and the gate insulating film GOX1 can be changed. If a voltage at the interface between the fin FIN1 and the gate insulating film GOX1 can be changed, the threshold voltage of the n-channel FINFET can be changed. Accordingly, in the fin FIN1 having a width of about 15 nm and a height of about 20 nm as illustrated in FIG. 8, the threshold voltage of the n-channel FINFET can be adjusted by changing the voltage to be applied to the first semiconductor region FSR1. In short, in the structure of the fin FIN1 as illustrated in FIG. 8, adjustment of a threshold voltage, which is the second characteristic of Embodiment 1, can be achieved.

Although not illustrated in FIG. 9, when the concentration of an n type impurity to be introduced into the first semiconductor region FSR1 is changed, the graph shown in FIG. 9 shifts in a vertical direction. For example, at a back bias of Vbg=0V, a change in the concentration of an n type impurity to be introduced into the first semiconductor region FSR1 leads to shift of a voltage at the interface between the fin FIN1 and the gate insulating film GOX1. Even at a back bias Vbg of −1V or a back bias Vbg of 1V, a voltage shifts similarly. Even if the back bias Vbg is equal, a change in the concentration of an n type impurity to be introduced into the first semiconductor region FSR1 shifts the voltage at the interface between the fin FIN1 and the gate insulating film GOX1. This means that a voltage at the interface between the fin FIN1 and the gate insulating film GOX1 can be changed by changing the concentration of an n type impurity to be introduced into the first semiconductor region FSR1, which means that when the voltage at the interface between the fin FIN1 and the gate insulating film GOX1 can be changed, the threshold voltage of the n-channel FINFET can be changed. Accordingly, it can be found that as illustrated in FIG. 8, in the fin FIN1 having a width of about 15 nm and a height of about 20 nm, the threshold voltage of the n-channel FINFET can be changed by changing the concentration of an n type impurity to be introduced into the first semiconductor region FSR1. This means that in the structure as illustrated in FIG. 8, the adjustment of a threshold voltage can be achieved according to the first characteristic of Embodiment 1. As described above, in the structure of the fin FIN1 as illustrated in FIG. 8, therefore, adjustment of the threshold voltage can be achieved according to the first characteristic and the second characteristic of Embodiment 1.

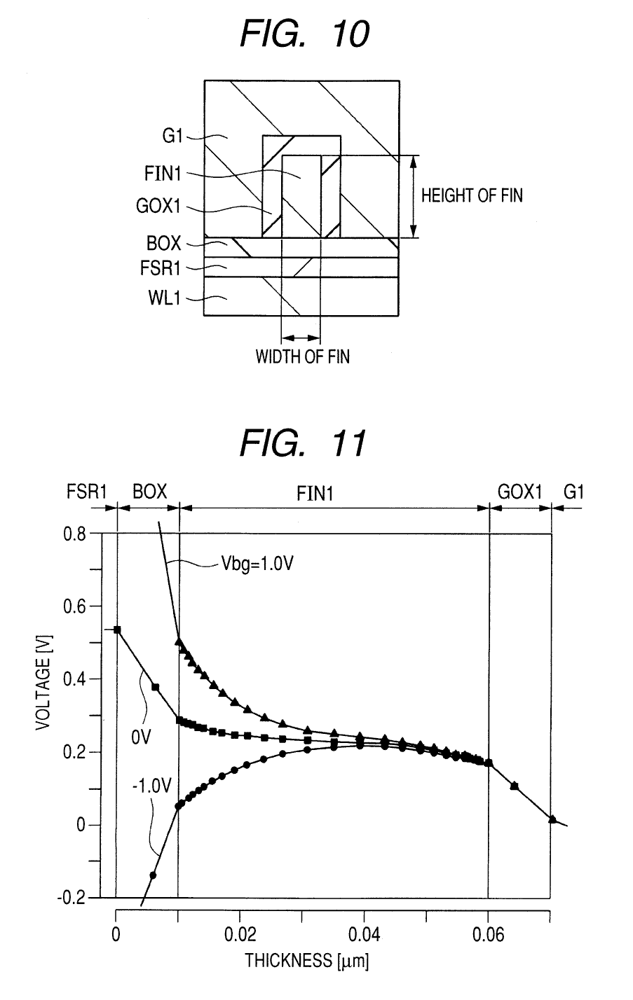

FIG. 10 is a cross-sectional view illustrating the configuration in the vicinity of the fin FIN1. In FIG. 10, the well WL1 has thereon the first semiconductor region FSR1 and this first semiconductor region FSR1 has thereon the buried insulating layer BOX. The buried insulating layer BOX has thereon the fin FIN1 and this fin FIN1 has, on the surface thereof, the gate insulating film GOX1. The gate electrode G1 is formed so as to cover therewith the fin FIN1. The fin FIN1 has a width of about 15 nm and a height of about 50 nm. A change caused by application of a back bias Vbg of from −1V to 1V to the first semiconductor region FSR1 of the n-channel FINFET having such a configuration will next be considered.

FIG. 11 is a graph showing a change in the potential (voltage) in the buried insulating layer BOX, the fin FIN1, and the gate insulating film GOX1 when a back bias Vbg of from V to 1V is applied to the first semiconductor region FSR1 of the n-channel FINFET. In FIG. 11, a thickness (distance) (μm) from the upper surface of the first semiconductor region FSR1 is plotted along the abscissa and a voltage (potential) is plotted along the ordinate.

FIG. 11 includes graphs at a back bias Vbg of 0V, a back bias Vbg of −1V, and a back bias Vbg of 1V. First, the graph at a back bias Vbg of 0V will be described. In this case, the voltage at the interface between the first semiconductor region FSR1 and the buried insulating layer BOX is about 0.53V. The voltage decreases toward the interface between the buried insulating layer BOX and the fin FIN1, at which it becomes 0.3V. Then, the voltage decreases mildly toward the interface between the fin FIN1 and the gate insulating film GOX1 (in other words, at the surface of the fin FIN1), at which it becomes about 0.2V.

Next, the graph at a back bias Vbg of −1V will be described. In this case, the voltage at the interface between the first semiconductor region FSR1 and the buried insulating layer BOX is too low and is therefore not shown in the graph. The voltage increases toward the interface between the buried insulating layer BOX and the fin FIN1, at which it becomes about 0.05V. Then, the voltage increases mildly toward the interface between the fin FIN1 and the gate insulating film GOX1 (in other words, at the surface of the fin FIN1), at which it becomes about 0.2V.

Further, the graph at a back bias Vbg of 1V will be described. In this case, the voltage at the interface between the first semiconductor region FSR1 and the buried insulating layer BOX is too high and is therefore not shown in the graph. The voltage decreases toward the interface between the buried insulating layer BOX and the fin FIN1, at which it becomes about 0.5V. Then, the voltage decreases mildly toward the interface between the fin FIN1 and the gate insulating film GOX1 (in other words, at the surface of the fin FIN1), at which it becomes about 0.2V.

From these three graphs, it has been found that no change in voltage occurs at the interface between the fin FIN1 and the gate insulating film GOX1. This means that even when a voltage to be applied to the first semiconductor region FSR1 is changed from −1V to 1V, a voltage at the interface between the fin FIN1 and the gate insulating film GOX1 cannot be changed. The fact that a voltage at the interface between the fin FIN1 and the gate insulating film GOX1 cannot be changed means that a threshold voltage of the n-channel FINFET cannot be changed. Accordingly, as illustrated in FIG. 10, in the fin FIN1 having a width of about 15 nm and a height of about 50 nm, the threshold voltage of the n-channel FINFET cannot be adjusted even by changing the voltage to be applied to the first semiconductor region FSR1. In short, in the structure of the fin FIN1 as illustrated in FIG. 10, adjustment of a threshold voltage cannot be achieved according to the second characteristic of Embodiment 1.

Although not illustrated in FIG. 11, when the concentration of an n type impurity to be introduced into the first semiconductor region FSR1 is changed, the voltage shifts at the interface between the buried insulating layer BOX and the fin FIN1 but the voltage does not shift at the interface between the fin FIN1 and the gate insulating film GOX1. Similarly at a back bias Vbg of −1V or a back bias Vbg of 1V, the voltage shifts at the interface between the buried insulating layer BOX and the fin FIN1 but the voltage does not shift at the interface between the fin FIN1 and the gate insulating film GOX1. In other words, when the back bias Vbg is the same, the voltage does not shift at the interface between the fin FIN1 and the gate insulating film GOX1 even by changing the concentration of an n type impurity introduced into the first semiconductor region FSR1. This means that even by changing the concentration of an n type impurity to be introduced into the first semiconductor region FSR1, the voltage at the interface between the fin FIN1 and the gate insulating film GOX1 cannot be changed, which means that when the voltage at the interface between the fin FIN1 and the gate insulating film GOX1 cannot be changed, the threshold voltage of the n-channel FINFET cannot be changed. Accordingly, it can be found that as illustrated in FIG. 10, in the fin FIN1 having a width of about 15 nm and a height of about 50 nm, the threshold voltage of the n-channel FINFET cannot be changed even by changing the concentration of an n type impurity to be introduced into the first semiconductor region FSR1. In the structure of the fin FIN1 as illustrated in FIG. 10, adjustment of a threshold voltage cannot be achieved according to the first characteristic of Embodiment 1. As described above, in the structure of the fin FIN1 as illustrated in FIG. 10, adjustment of a threshold voltage cannot be achieved according to the first characteristic and the second characteristic of Embodiment 1.

As a result, as the height of the fin FIN1 becomes greater relative to its width, it becomes difficult to adjust the threshold voltage according to the first characteristic and the second characteristic of Embodiment 1. It is therefore apparent from FIG. 11 that in the graphs at a back bias Vbg of 0V, a back bias Vbg of −1V, and a back bias Vbg of 1V, the height of the fin is up to about 30 nm to provide a difference in the voltage at the interface between the fin FIN1 and the gate insulating film GOX1. The width of the fin FIN1 is 15 nm so that adjustment of a threshold voltage can be achieved when a ratio of the height of the fin FIN1 relative to the width of the fin is 1 or greater but not greater than 2. Adjustment of a threshold voltage according to the first characteristic and the second characteristic of Embodiment 1 can be effectively performed when a ratio of the height of the fin FIN1 to the width of the fin is 1 or greater but not greater than 2. The semiconductor device of Embodiment 1 has the above-described configuration. A manufacturing method of it will next be described referring to some drawings. In the semiconductor device according to Embodiment 1, both a FINFET and a planar type MISFET are mounted on the same semiconductor substrate. Accordingly, in the manufacturing method of a semiconductor device in Embodiment 1, a step of simultaneously forming a FINFET and a planar type MISFET will be described.

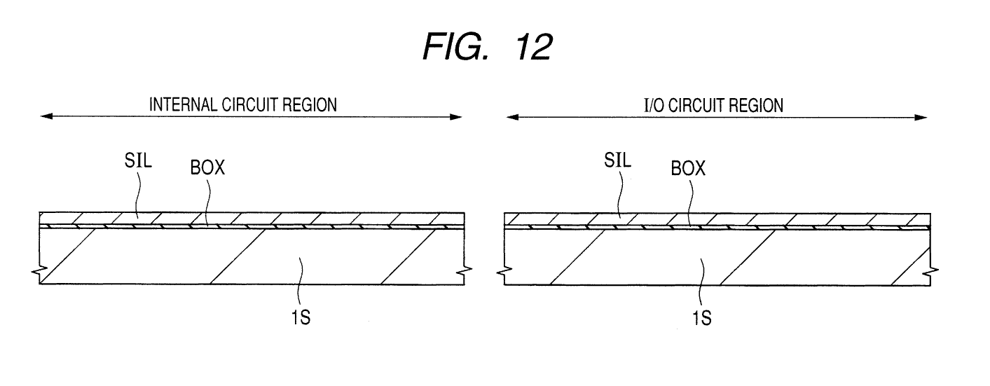

As illustrated in FIG. 12, an SOI substrate comprised of a substrate layer 1S, a buried insulating layer BOX formed on the substrate layer 1S, and a silicon layer SIL formed on the buried insulating layer BOX is prepared. The SOI substrate can be obtained, for example, by thermal compression bonding of a semiconductor substrate (semiconductor wafer) having, on the surface thereof, a silicon oxide film with another semiconductor substrate and then grinding or removing a portion of one of the semiconductor substrates. Alternatively, the SOI substrate can be prepared by implanting a semiconductor substrate with oxygen ions at a high energy (180 keV or less) and a high concentration (1×10¹⁸ atoms/cm² or less) and then heat treating the resulting semiconductor substrate at high temperature, thereby forming a buried insulating layer inside of the semiconductor substrate.

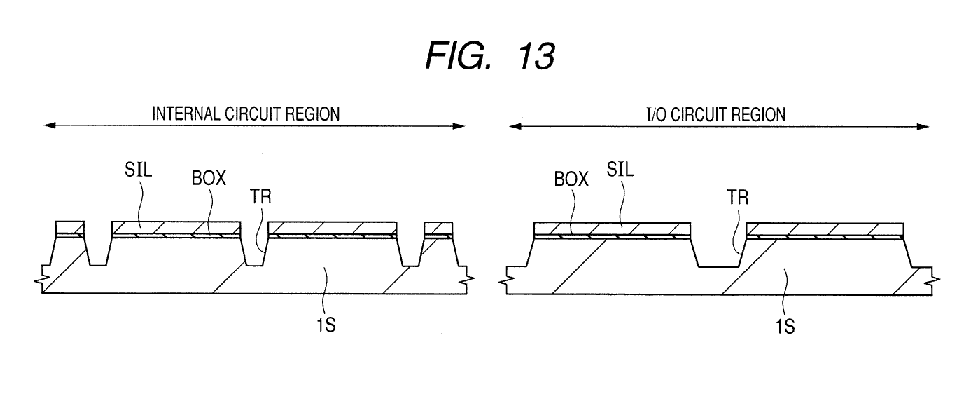

Then, as illustrated in FIG. 13, a trench TR is formed in the SOI substrate by photolithography and etching. The trench TR is formed in each of an internal circuit region and an I/O circuit region. This trench TR penetrates through the silicon layer SIL and the buried insulating layer BOX of the SOI substrate and reaches the substrate layer 1S.

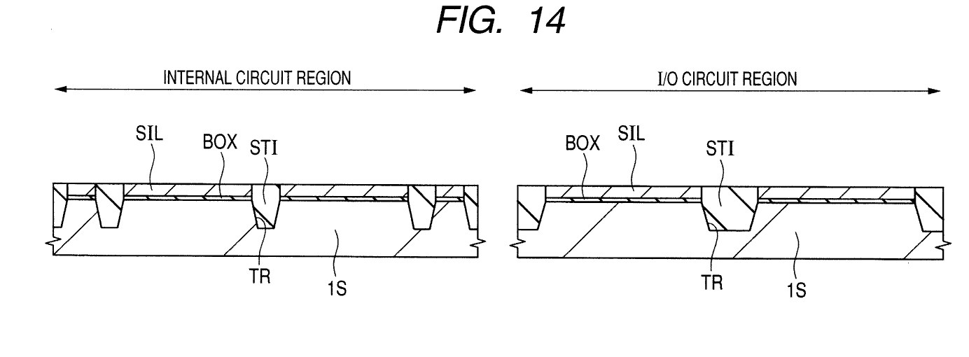

Then, as illustrated in FIG. 14, a silicon oxide film is formed on the SOI substrate having the trench TR formed therein and the silicon oxide film is filled in the trench TR. An unnecessary portion of the silicon oxide film formed on the SOI substrate is removed, for example, by using CMP (chemical mechanical polishing) to leave the silicon oxide film only inside of the trench TR. In such a manner, the trench TR filled with the silicon oxide film is formed as an element isolation region STI.

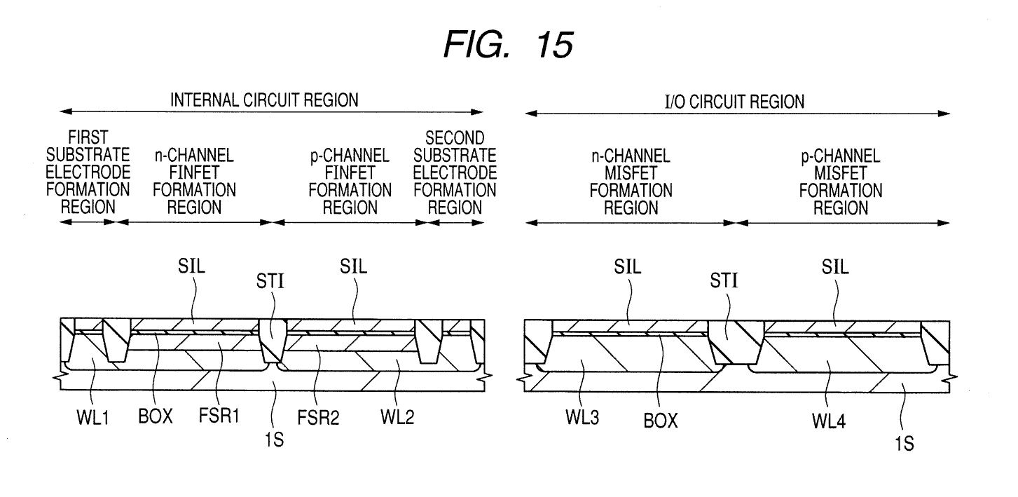

As illustrated in FIG. 15, a well WL1, which is an n type semiconductor region, is formed in the substrate layer 1S of a first substrate electrode formation region and an n-channel FINFET formation region located in the internal circuit region by using photolithography and ion implantation. Similarly, a well WL2, which is a p type semiconductor region, is formed in a second substrate electrode formation region and a p-channel FINFET formation region located in the internal circuit region by using photolithography and ion implantation. On the other hand, even in the I/O circuit region, a well WL3, which is a p type semiconductor region, is formed in an n-channel MISFET formation region and a well WL4, which is an n type semiconductor region, is formed in a p-channel MISFET formation region by using photolithography and ion implantation.

Further, a first semiconductor region FSR1, which is an n type semiconductor region, is formed in the n-channel FINFET formation region in the internal circuit region by using photolithography and ion implantation. Similarly, a first semiconductor region FSR2, which is a p type semiconductor region, is formed in the p-channel FINFET formation region in the internal circuit region by using photolithography and ion implantation. In such a manner, in the n-channel FINFET formation region, the well WL1 is formed in the substrate layer 1S and the first semiconductor region FSR1 contiguous to the buried insulating layer BOX is formed on the well WL1. Similarly, in the p-channel FINFET formation region, the well WL2 is formed in the substrate layer 1S and the first semiconductor region FSR2 contiguous to the buried insulating layer BOX is formed on the well WL2.

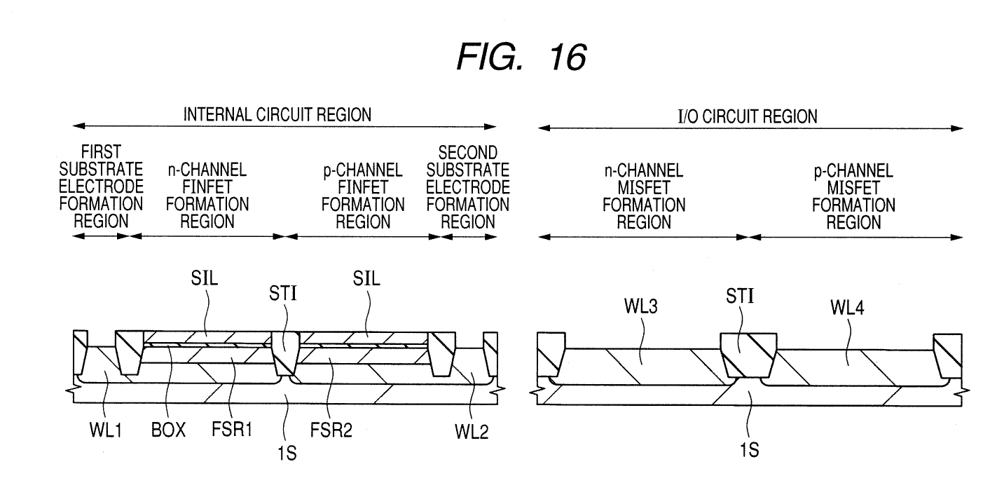

As illustrated in FIG. 16, the silicon layer SIL and the buried insulating layer BOX are removed from the first substrate electrode formation region and the second substrate electrode formation region in the internal circuit region by using photolithography and etching. At the same time, the silicon layer SIL and the buried insulating layer BOX are removed from the n-channel MISFET formation region and the p-channel MISFET formation region in the I/O circuit region. As a result, the surfaces of the well WL1 and the well WL2 are exposed in the first substrate electrode formation region and the second substrate electrode formation region, respectively. Also from the n-channel MISFET formation region and the p-channel MISFET formation region, the surfaces of the well WL3 and the well WL4 are exposed, respectively. The SOI substrate can be processed in such a manner.

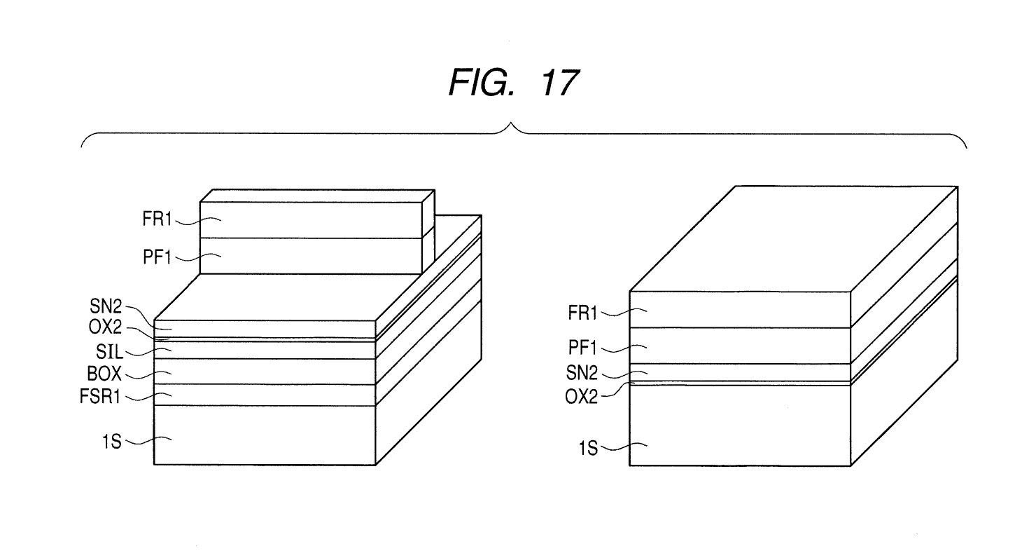

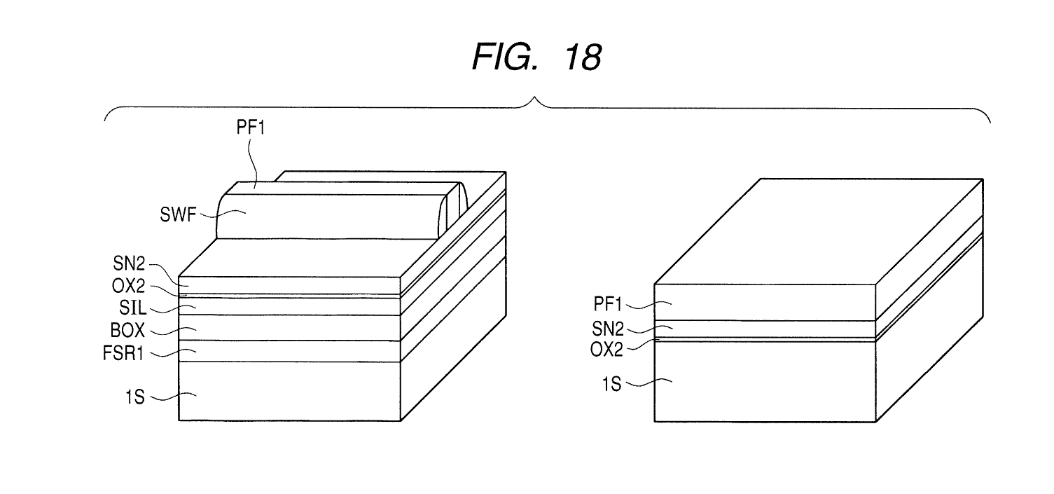

Then, FINFETs (an n-channel FINFET and a p-channel FINFET) and planar type MISFETs (an n-channel MISFET and a p-channel MISFET) are formed on the SOI substrate thus processed. In the following steps, a description will be made with the re-channel FINFET and the n-channel MISFET as examples. In the manufacturing steps after the processing of the SOI substrate, a description will be made referring to perspective views to facilitate understanding. In FIGS. 17 to 33, the n-channel FINFET formation region is illustrated on the left side and the n-channel MISFET formation region is illustrated on the right side.

As illustrated in FIG. 17, in the n-channel FINFET formation region, a silicon oxide film OX2 is formed on the silicon layer SIL of the SOI substrate and a silicon nitride film SN2 is formed on the silicon oxide film OX2. On the other hand, in the n-channel MISFET formation region, a silicon oxide film OX2 is formed on the substrate layer 1S (on a well not illustrated in detail) of the SOI substrate and a silicon nitride film SN2 is formed on the silicon oxide film OX2. The silicon oxide film OX2 can be formed, for example, by thermal oxidation and the silicon nitride film SN2 can be formed, for example, by CVD (chemical vapor deposition). A polysilicon film PF1 is formed on the silicon nitride film SN2 formed in the n-channel FINFET formation region. Also in the n-channel MISFET formation region, a polysilicon film PF1 is formed on the silicon nitride film SN2. Then, a resist film FR1 is formed on the polysilicon film PF1. The resist film FR1 is then patterned by using photolithography. The resist film FR1 is patterned so as to leave the resist film FR1 in a dummy pattern formation region in the n-channel FINFET formation region and leave the resist film FR1 on the entire surface in the n-channel MISFET formation region. The polysilicon film PF1 is processed by etching with the patterned resist film FR1 as a mask. As a result, a dummy pattern is formed in the re-channel FINFET formation region.

As illustrated in FIG. 18, after removal of the patterned resist film FR1, a silicon oxide film is formed over the re-channel FINFET formation region and the n-channel MISFET formation region. The silicon oxide film can be formed, for example, by CVD. By anisotropic etching of the silicon oxide film, a sidewall SWF comprised of the silicon oxide film is formed on the side surfaces of the polysilicon film PF1 (dummy pattern) in the n-channel FINFET formation region. On the other hand, in the n-channel MISFET formation region, the silicon oxide film is removed completely to expose the polysilicon film PF1.

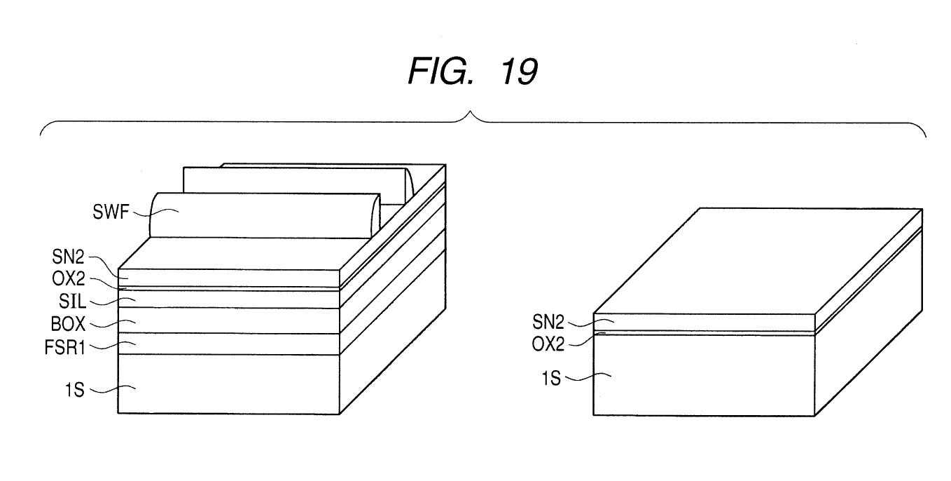

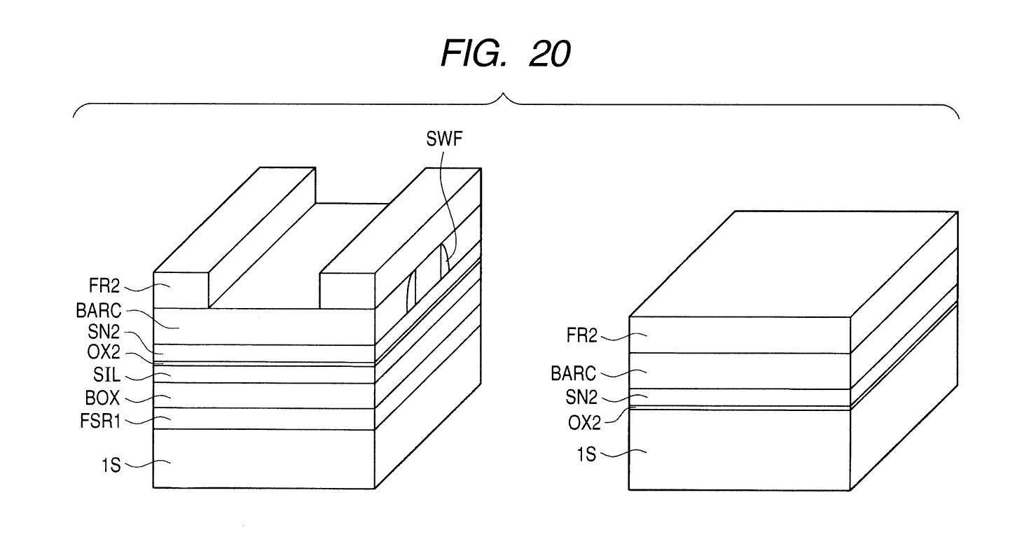

As illustrated in FIG. 19, the exposed polysilicon film PF1 is removed. Removal of the polysilicon film PF1 can be carried out, for example, by wet etching. In the n-channel FINFET formation region, the polysilicon film PF1 sandwiched between the sidewalls SWF are removed and in the n-channel MISFET formation region, the polysilicon film PF1 is removed completely to expose the silicon nitride film SN2. This sidewall SWF determines the fin width of the n-channel FINFET. In Embodiment 1, since the width of the sidewall SWF that determines the fin width of the n-channel FINFET is determined not by photolithography but the deposition thickness of the silicon oxide film so that the line width of the sidewall SW becomes uniform. Accordingly, it is possible to form a fin having a thin and uniform width by processing the fin with the sidewall SWF as a mask.

As illustrated in FIG. 20, in the n-channel FINFET formation region, an antireflective film BARC is formed on the silicon nitride film SN2 having thereon the sidewall SWF and then, a resist film FR2 is formed on this antireflective film BARC. In the n-channel MISFET formation region, on the other hand, an antireflective film BARC is formed on the silicon nitride film SN2 and a resist film FR2 is formed on the antireflective film BARC. Then, the resist film FR2 is patterned by using photolithography. The patterning of the resist film FR2 in the n-channel FINFET formation region is performed while leaving the resist film FR2 in a region where the source region and the drain region are formed, while the patterning in the n-channel MISFET formation region is performed while leaving the resist film FR2 on the entire surface.

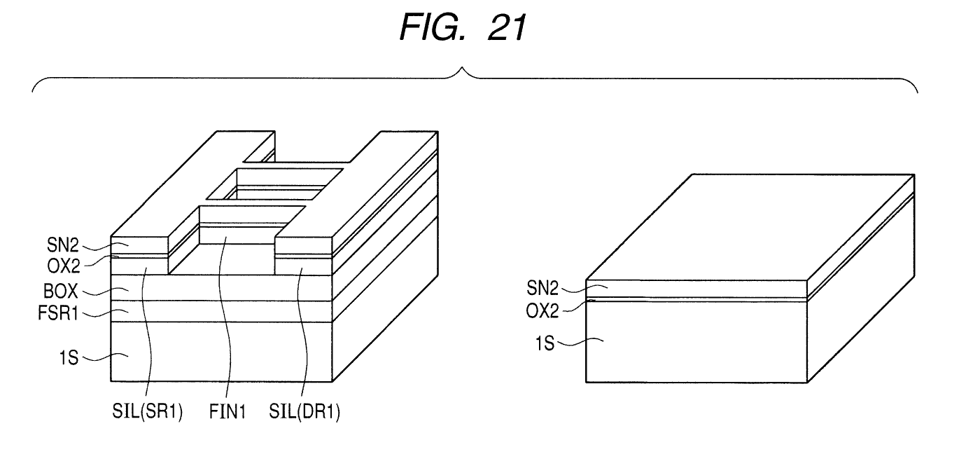

Then, as illustrated in FIG. 21, with the patterned resist film FR2 as a mask, the antireflective film BARC and the silicon nitride film SN2 are patterned. In this patterning of the silicon nitride film SN2, not only the resist film FR2 but also the sidewall SWF made of the silicon oxide film serves as a mask. Then, the silicon oxide film OX2 and the silicon layer SIL lying below the silicon nitride film SN2 are patterned further. As a result, the silicon layer SIL is processed into a fin FIN1 in a rectangular solid form, a source region SR1 coupled to one end of the fin FIN1, and a drain region DR1 coupled to the other end of the fin FIN1. After the patterning, the antireflective film BARC and the resist film FR2 are removed. In such a manner, the fin FIN1 in a rectangular solid form, the source region SR1, and the drain region DR1 are formed in the n-channel FINFET formation region. On the other hand, in the n-channel MISFET formation region, the silicon nitride film SN2 is exposed. When the fin is formed, a ratio of the fin height of the fin FIN1 to the fin width is adjusted to 1 or greater but not greater than 2.

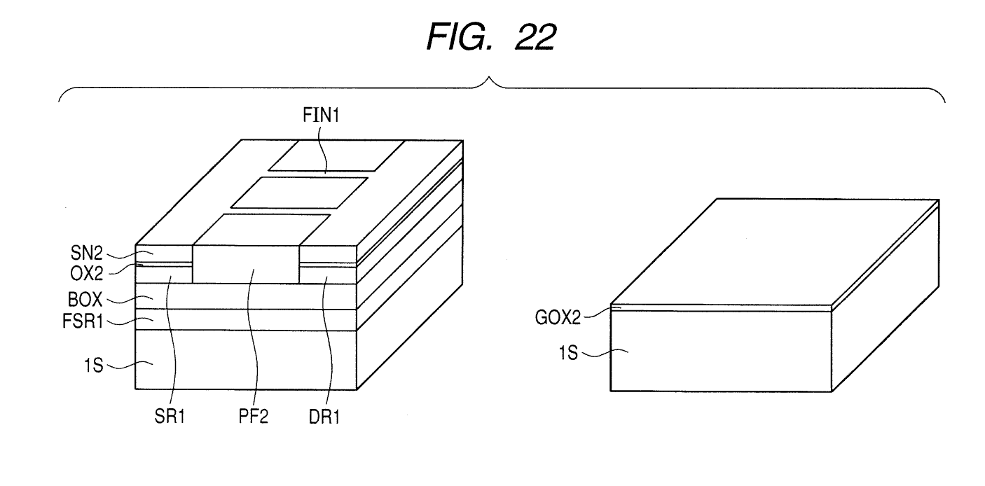

Next, as illustrated in FIG. 22, in the n-channel FINFET formation region, a gate insulating film (not illustrated) is formed on the surface of the fin FIN1, while a gate insulating film GOX2 is formed on the substrate layer 1S in the n-channel MISFET formation region. The gate insulating film (not illustrated) and the gate insulating film GOX2 are each made of, for example, a silicon oxide film.

The gate insulating film is however not limited to the silicon oxide film and various ones can be used instead. For example, a silicon oxynitride film (SiON) may be used as the gate insulating film. The silicon oxynitride film is more effective than the silicon oxide film in suppressing generation of an interface state in the film or reducing electron traps. Using it can therefore improve hot carrier resistance of the gate insulating film and improving insulation resistance. In addition, compared with the silicon oxide film, the silicon oxynitride film does not allow easy penetration of impurities. Using the silicon oxynitride film as the gate insulating film can therefore suppress variations in threshold voltage which will otherwise occur due to diffusion of impurities from a gate electrode to the side of the fin FIN1 or the substrate layer 1S.

The gate insulating film may be formed of a high dielectric constant film having a higher dielectric constant than the silicon oxide film. From the standpoint that the silicon oxide film has high insulation resistance and excellent electrical/physical stability on a silicon-silicon oxide interface, the silicon oxide film is conventionally used as the gate insulating film. With device scaling, however, the gate insulating film has been required to be ultra thin. Using such a thin silicon oxide film as the gate insulating film however inevitably causes so-called tunneling current, that is, electrons flowing in the channel of a MISFET tunnel through a barrier formed by the silicon oxide film and flow into a gate electrode.

In order to avoid this, a high dielectric constant film made of a material having a higher dielectric constant than the silicon oxide film and having an increased physical film thickness even without having the capacitance changed has come to be used. When the high dielectric constant film is used, a physical film thickness can be increased without changing the capacitance so that a leakage current can be reduced. In particular, a silicon nitride film has a higher dielectric constant than the silicon oxide film, but using a high dielectric constant film having a higher dielectric constant than the silicon nitride film is desired in Embodiment 1.

For example, as the high dielectric constant film having a higher dielectric constant than a silicon nitride film, a hafnium oxide (HfO₂ film), which is one of hafnium oxides, is used. Instead of the hafnium oxide film, another hafnium insulating film such as HfAlO film (hafnium aluminate film), HfON film (hafnium oxynitride film), HfSiO film (hafnium silicate film), or HfSiON film (hafnium silicon oxynitride film) can be used. Further, a hafnium insulating film obtained by introducing an oxide such as tantalum oxide, niobium oxide, titanium oxide, zirconium oxide, lanthanum oxide, or yttrium oxide into the above-described hafnium insulating film can also be used. The hafnium insulating film has, similar to the hafnium oxide film, a higher dielectric constant than a silicon oxide film or silicon oxynitride film so that effects similar to those produced by using the hafnium oxide film can be attained.

A polysilicon film PF2 is then formed on the entire surface in the n-channel FINFET formation region and the re-channel MISFET formation region. Next, the polysilicon film PF2 is processed by using CMP until the surface of the silicon nitride film SN2 is exposed. In the n-channel MISFET formation region, on the other hand, the polysilicon film PF2 is removed.

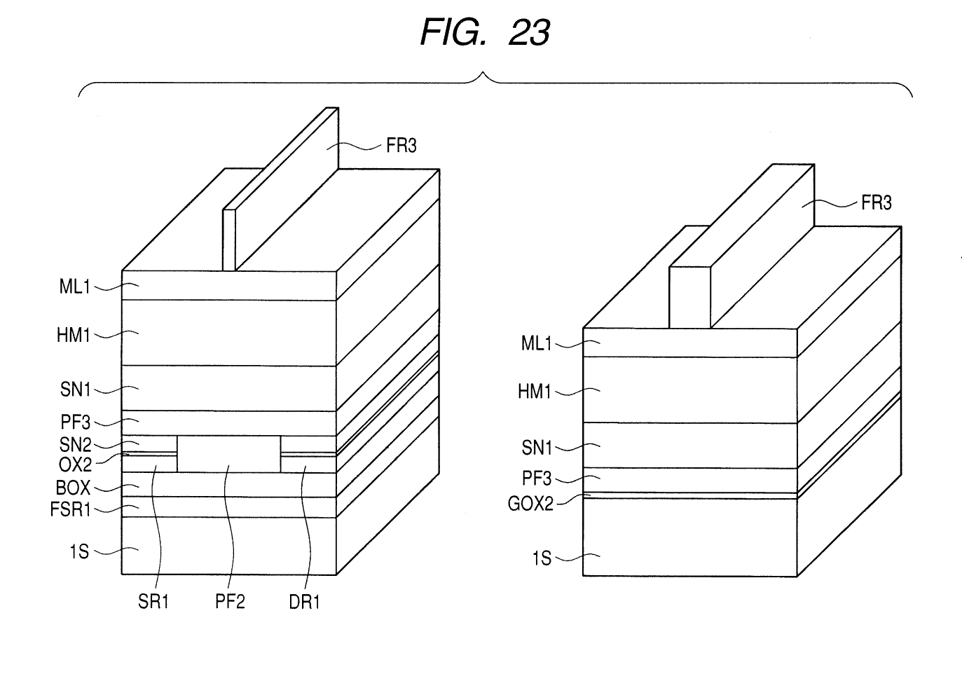

As illustrated in FIG. 23, in the n-channel FINFET formation region, a polysilicon film PF3 is formed on the polysilicon film PF2 and the silicon nitride film SN2, which have been planarized, and a silicon nitride film SN1 is formed on the resulting polysilicon film PF3. In the n-channel MISFET formation region, on the other hand, a polysilicon film PF3 is formed on the gate insulating film GOX2 and a silicon nitride film SN1 is formed on the resulting polysilicon film PF3. The polysilicon film PF3 and the silicon nitride film SN1 can be formed, for example, by CVD. In the n-channel FINFET formation region and the n-channel MISFET formation region, a hard mask film HM1 containing carbon is formed on the silicon nitride film SN1 and an intermediate layer ML1 containing silicon is formed on the resulting hard mask film HM1. A resist film FR3 is then formed on the intermediate layer ML1. The resist film FR3 is then patterned by using photolithography. The patterning of the resist film FR3 is performed so as to leave the resist film FR3 in a gate electrode formation region.

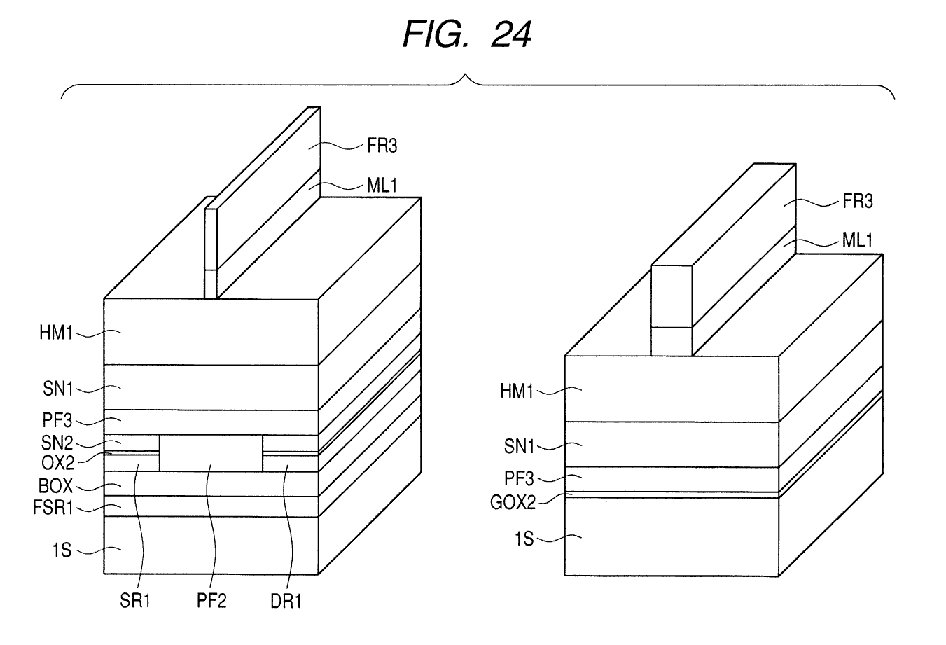

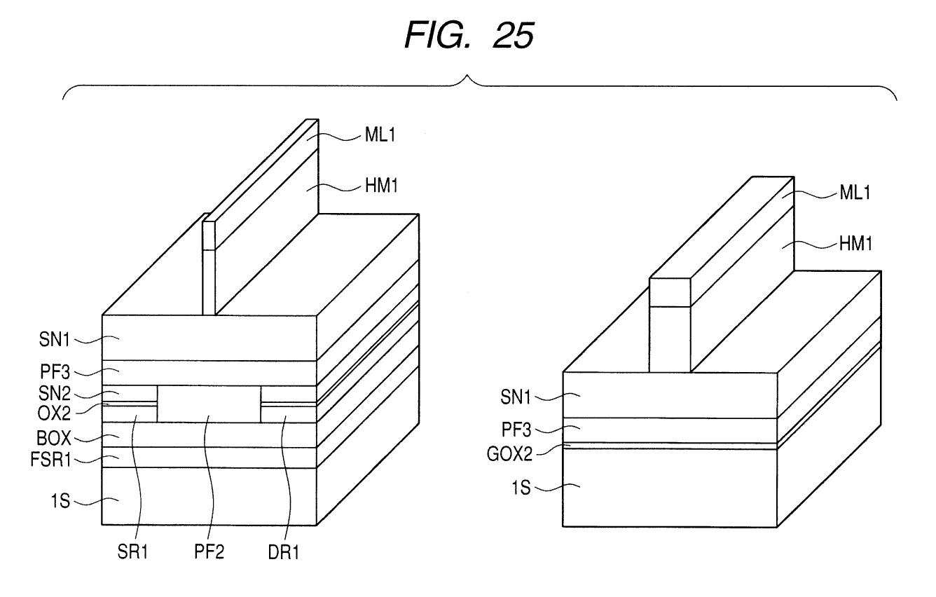

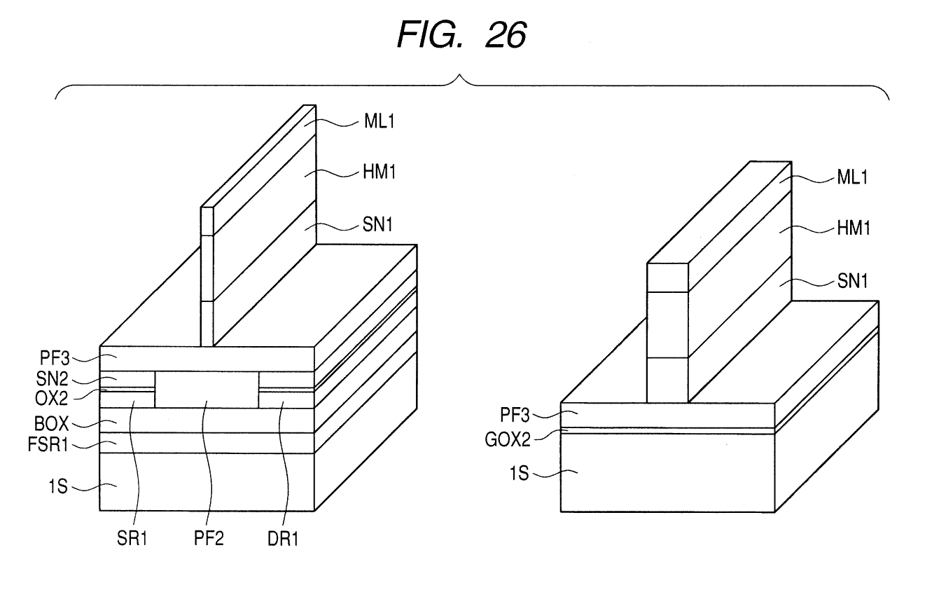

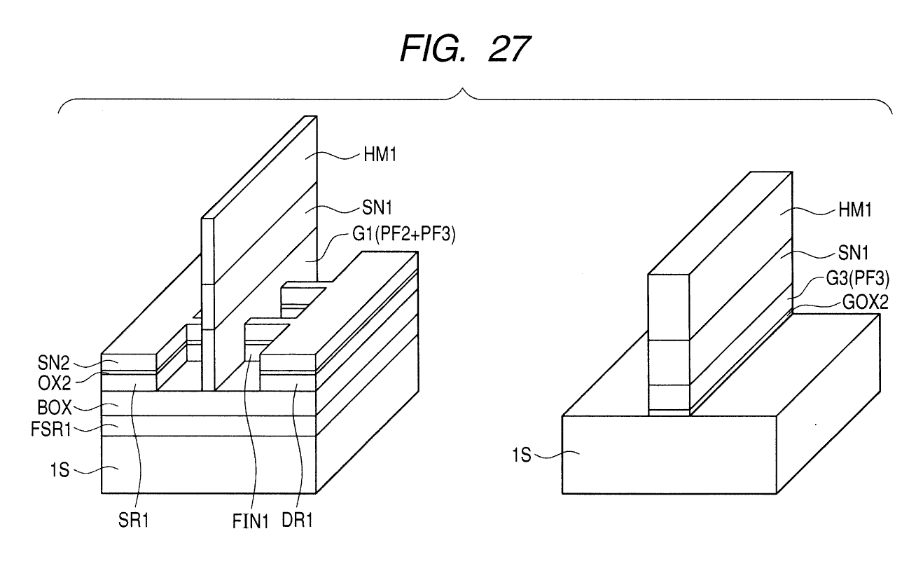

As illustrated in FIG. 24, with the patterned resist film FR3 as a mask, etching is performed to pattern the intermediate layer ML1. After removal of the patterned resist film FR3, the hard mask film HM1 is patterned as illustrated in FIG. 25 by using the patterned intermediate layer ML1 as a mask. As illustrated in FIG. 26, the silicon nitride film SN1 is then patterned with the patterned intermediate layer ML1 and hard mask film HM1 as masks. After removal of the intermediate layer ML1, the polysilicon film PF3 and the polysilicon film PF2 are patterned as illustrated in FIG. 27 by using the patterned hard mask film HM1 and silicon nitride film SN1 as masks. As a result, in the n-channel FINFET formation region, a gate electrode G1 straddling over the surface of the fin FIN1 via a gate insulating film not illustrated is formed in a region extending in a direction intersecting with the extending direction of the fin FIN1 and at the same time intersecting with the fin FIN1. In the re-channel MISFET formation region, on the other hand, a gate electrode G3 is formed on the gate insulating film GOX2.

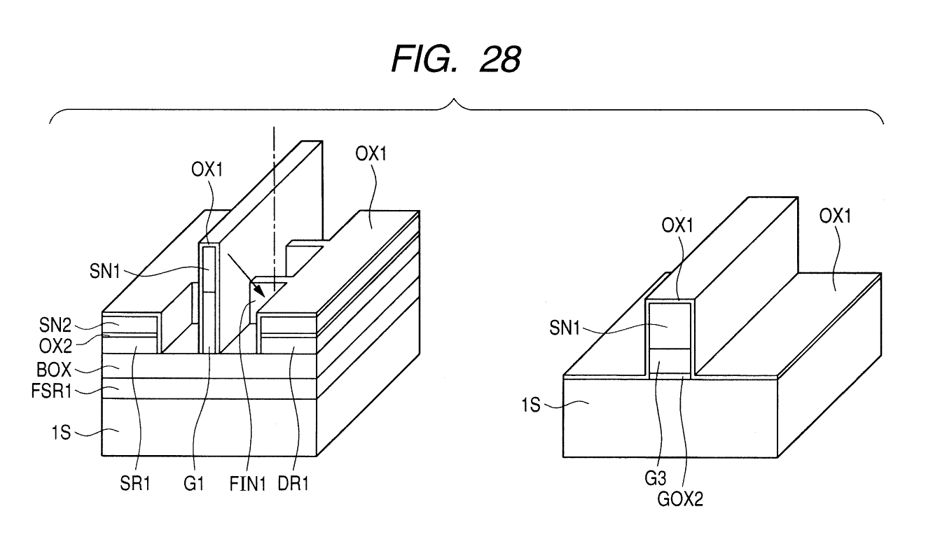

Then, as illustrated in FIG. 28, after removal of the hard mask film HM1, a silicon oxide film OX1 is formed on the entire surface in the n-channel FINFET formation region and the n-channel MISFET formation region. An n type impurity such as phosphorus (P) or arsenic (As) is introduced into the source region SR1 and the drain region DR1 (including also a portion of the fin FIN1 not covered with the gate electrode G1) which are formed in the n-channel FINFET formation region by using photolithography and oblique ion implantation. The impurity is implanted to the fin FIN1 obliquely from both sides.

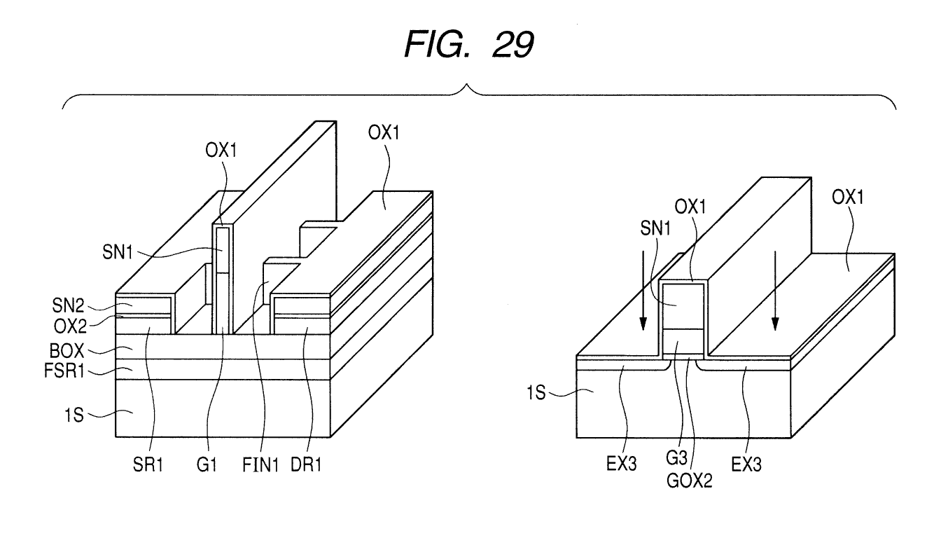

As illustrated in FIG. 29, an n type impurity such as phosphorus (P) or arsenic (As) is then introduced into the substrate layer 1S in alignment with the gate electrode G3 formed in the n-channel MISFET formation region by using photolithography and ion implantation, by which a shallow n-type impurity diffusion region EX3 is formed. Then, activation annealing (heat treatment) is performed to activate the impurity thus introduced.

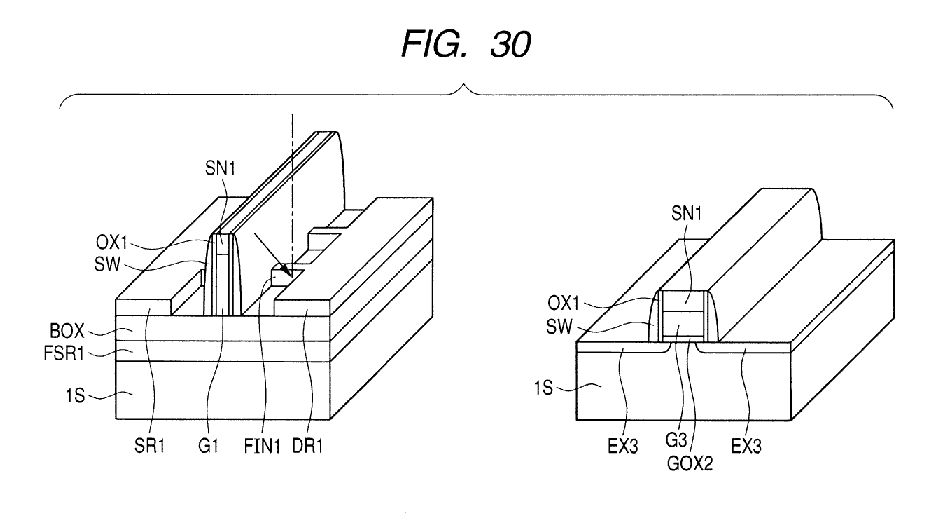

As illustrated in FIG. 30, after formation of a silicon nitride film on the entire surface including the n-channel FINFET formation region and the n-channel MISFET formation region, the silicon nitride film is then anisotropically etched, whereby a sidewall SW is formed on the side surfaces of the gate electrode G1 via the silicon oxide film OX1 in the n-channel FINFET formation region. The silicon nitride film SN2 and the silicon oxide film OX2 formed on the source region SR1 and the drain region DR1 (including a portion of the fin FIN1 not covered with the gate electrode G1) have already been removed. In the n-channel MISFET formation region, on the other hand, a sidewall SW is formed on the side surfaces of the gate electrode G3 via the silicon oxide film OX1. The silicon oxide film OX1 formed on the shallow n-type impurity diffusion region EX3 has already been removed. An n-type impurity such as phosphorus (P) or arsenic (As) is introduced into the source region SR1 and the drain region DR1 (including a portion of the fin FIN1 not covered with the sidewall SW) formed in the n-channel FINFET formation region by using photolithography and oblique ion implantation. The impurity ion is implanted to the fin FIN1 obliquely from both sides.

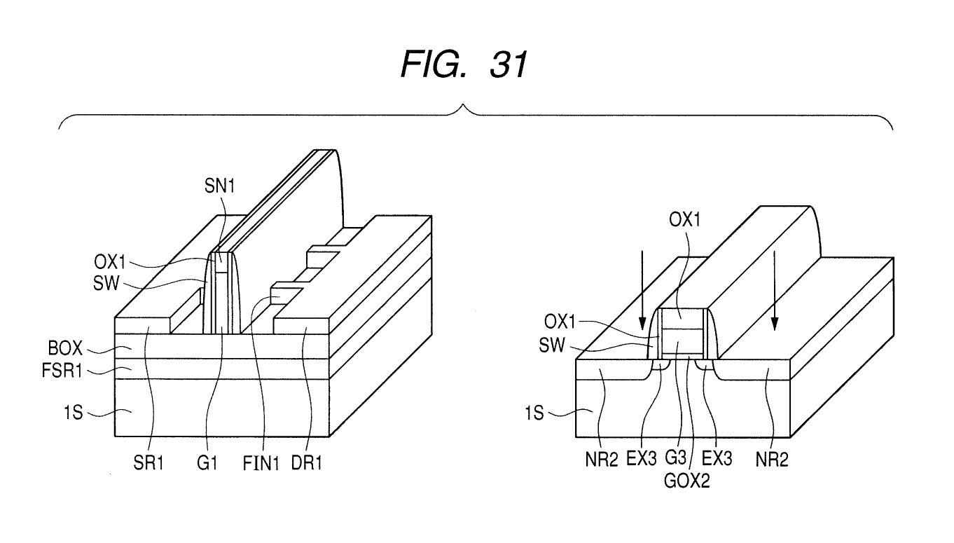

As illustrated in FIG. 31, an n type impurity such as phosphorus (P) or arsenic (As) is then introduced into the substrate layer 1S in alignment with the sidewall SW formed in the n-channel MISFET formation region, by which a deep n-type impurity diffusion region NR2 is formed. Then, activation annealing (heat treatment) is performed to activate the impurity thus introduced.

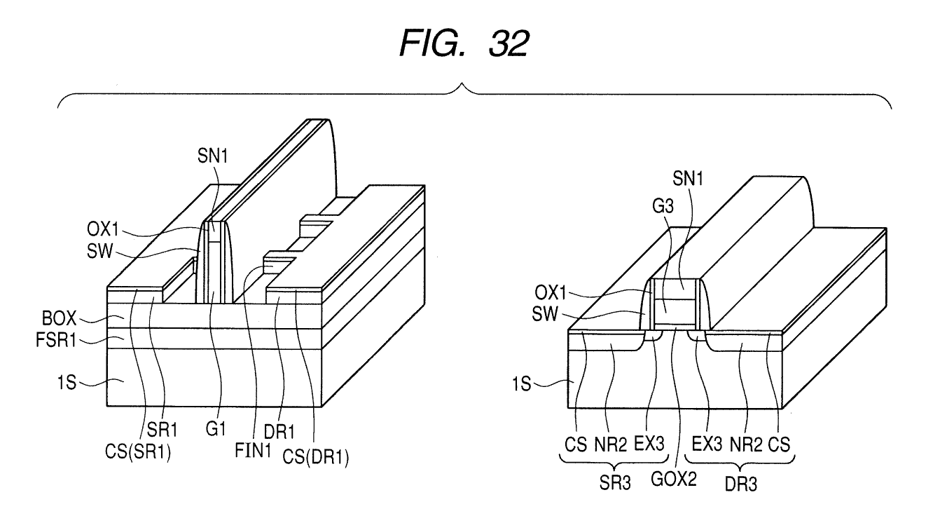

As illustrated in FIG. 32, after formation of a cobalt film on the entire surface including the n-channel FINFET formation region and the n-channel MISFET formation region, heat treatment is performed, by which, in the n-channel FINFET formation region, a cobalt silicide film CS is formed on the source region SR1, the drain region DR1, and the exposed surface of the fin FIN1. In the n-channel MISFET formation region, on the other hand, a cobalt silicide film CS is formed on the surface of the deep n-type impurity diffusion region NR2. The cobalt silicide film CS is formed in Embodiment 1, but the cobalt silicide film CS may be replaced with, for example, a nickel silicide film, a titanium silicide film, or a platinum silicide film. In such a manner, the n-channel FINFET is formed in the n-channel FINFET formation region and the n-channel MISFET is formed in the n-channel MISFET formation region.

As illustrated in FIG. 33, a contact interlayer insulating film CIL is thereafter formed on the semiconductor substrate (substrate layer 1S) having thereon the n-channel FINFET and the n-channel MISFET. This contact interlayer insulating film CIL covers therewith the n-channel FINFET and the n-channel MISFET. Described specifically, the contact interlayer insulating film CIL is made of a film stack of, for example, an ozone TEOS film formed by thermal CVD by using, for example, ozone and TEOS as raw materials and a plasma TEOS film formed by plasma CVD by using TEOS as a raw material. The ozone TEOS film may have, therebelow an etching stopper film made of, for example, a silicon nitride film.

The contact interlayer insulating film CIL is made of a TEOS film because the TEOS film covers irregularities lying therebelow with good coverage. Below the contact interlayer insulating film CIL, there are irregularities resulting from the n-channel FINFET and the n-channel MISFET formed over the semiconductor substrate (substrate layer 1S). In other words, since the n-channel FINFET and the n-channel MISFET are formed over the semiconductor substrate (substrate layer 1S), the interlayer insulating film has therebelow irregularities due to the gate electrodes G1 and G3 on the surface of the semiconductor substrate (substrate layer 1S). If a film does not have a good coverage property of irregularities, minute irregularities remain unfilled and they become a cause for voids and the like. The TEOS film is therefore used as the contact interlayer insulating film CIL. In the TEOS film, TEOS used as a raw material forms an intermediate prior to the formation of a silicon oxide film and moves easily on the surface of the film formed, leading to improvement in the coverage of the underlying step difference.

Next, a contact hole is formed in the contact interlayer insulating film CIL by using photolithography and etching. The resulting contact hole penetrates through the contact interlayer insulating film CIL and reaches the source region or drain region of the n-channel FINFET or the n-channel MISFET formed in the semiconductor substrate (substrate layer 1S).

Then, a metal film is filled in the contact hole formed in the contact interlayer insulating film CIL to form a plug PLG1 or plug PLG2. Described specifically, a titanium/titanium nitride film (a titanium film and a titanium nitride film formed on the titanium film) which will be a barrier conductor film is formed on the contact interlayer insulating film CIL having therein the contact hole, for example, by sputtering. This titanium/titanium nitride film is provided in order to prevent diffusion of tungsten configuring the tungsten film into silicon. In CVD for reducing WF₆ (tungsten fluoride) in the formation of the tungsten film, the titanium/titanium nitride film prevents the contact interlayer insulating film CIL or semiconductor substrate (substrate layer 1S) from being damaged by fluorine attack.

A tungsten film is then formed on the titanium/titanium nitride film. As a result, the titanium/titanium nitride film is formed on the inner wall (side wall and bottom surface) of the contact hole and a tungsten film is filled in the contact hole on this titanium/titanium nitride film. An unnecessary portion of the titanium/titanium nitride film formed on the contact interlayer insulating film CIL is then removed by CMP (chemical mechanical polishing), whereby the plug PLG1 and the plug PLG2 obtained by filling the titanium/titanium nitride film and the tungsten film only in the contact hole can be formed.

Next, a step of forming a copper interconnect by using the single damascene process will be described. As illustrated in FIG. 33, an interlayer insulating film is formed on the contact interlayer insulating film CIL having therein the plug PLG1 and the plug PLG2. This interlayer insulating film is made of, for example, a silicon oxide film and this silicon oxide film can be formed, for example, by CVD.

A trench (interconnect trench) is formed in the interlayer insulating film by using photolithography and etching. This trench penetrates through the interlayer insulating film made of a silicon oxide film and reaches, at the bottom surface thereof, the contact interlayer insulating film CIL. The surfaces of the plug PLG1 and the plug PLG2 are therefore exposed from the bottom of the trench.

A barrier conductor film is then formed on the interlayer insulating film having therein the trench. Described specifically, the barrier conductor film is made of tantalum (Ta), titanium (Ti), ruthenium (Ru), tungsten (W), or manganese (Mn), a nitride or silicon nitride thereof, or a film stack of some of them and it can be formed, for example, by sputtering. In other words, the barrier conductor film can be made of either one of a metal material film having any of metal materials such as tantalum, titanium, ruthenium, and manganese or a compound film made of the metal material and any of elements such as Si, N, O, and C.

Then, a seed film comprised of, for example, a thin copper film is formed on the barrier conductor film formed in the trench and on the interlayer insulating film by sputtering. Then, by using the seed film as an electrode, a copper film is formed by electroplating. This copper film is filled in the trench. The copper film is comprised of a film composed mainly of copper. Described specifically, it is made of copper (Cu) or a copper alloy (copper (Cu) alloy with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), In (indium), a lanthanoid metal, or an actinoid metal).

An unnecessary portion of the barrier conductor film and the copper film formed on the interlayer insulating film is then removed by CMP, whereby an interconnect L1 having the trench filled with the barrier conductor film and the copper film can be formed. In such a manner, the semiconductor device of Embodiment 1 can be manufactured.

### Embodiment 2

In Embodiment 1, as illustrated in FIG. 28, an n-type impurity such as phosphorus (P) or arsenic (As) is introduced into the source region SR1 and the drain region DR1 (including a portion of the fin FIN1 not covered with the gate electrode G1) formed in the n-channel FINFET formation region by using photolithography and oblique ion implantation. In short, ion implantation is employed as a method for introducing an impurity into the fin FIN1 not covered with the gate electrode G1. In this case, it is desired to lower the resistance of the fin FIN1 from the standpoint of improving the characteristics of the FINFET. It is necessary to control the dosage of an impurity and an implantation energy in order to lower the resistance of the fin FIN1.

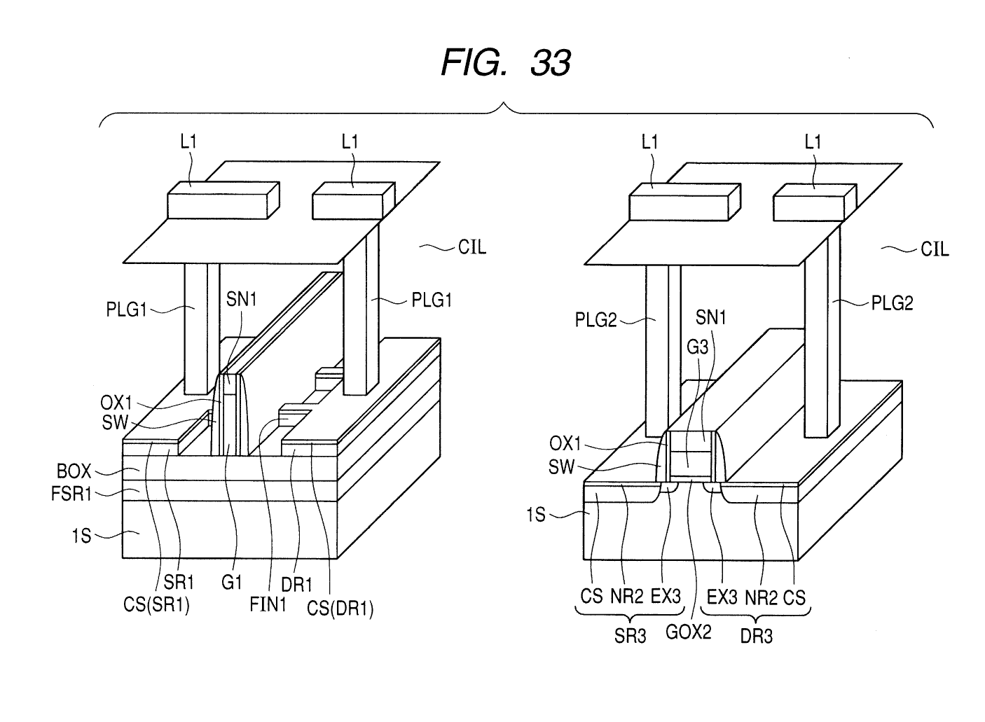

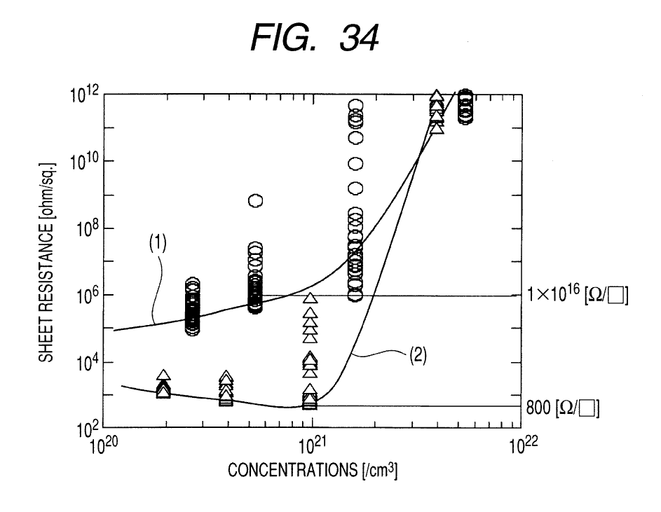

FIG. 34 is a graph showing the relationship between the sheet resistance of the fin FIN1 and the dosage of an impurity introduced into the fin FIN1. In FIG. 34, the dosage of an impurity is plotted along the abscissa and the sheet resistance is plotted along the ordinate. FIG. 34 includes two curves: one curve (1) shows the sheet resistance when an impurity is implanted at a high energy and the other curve (2) shows the sheet resistance when an impurity is implanted at a low energy. As is apparent from the curve (1), the sheet resistance and the variation in sheet resistance increase when an impurity is implanted at a high energy. It is also apparent that the sheet resistance increases with an increase in the dosage of an impurity.

It is apparent from the curve (2) that when an impurity is implanted at a low energy, the sheet resistance and the variation in the sheet resistance can be made smaller compared with the curve (1) when the impurity is implanted at a high energy. In particular, the curve (2) shows that with an increase in the dosage of an impurity, the sheet resistance shows a decreasing tendency. When it exceeds a certain dosage, however, the sheet resistance and the variation in the sheet resistance increase drastically. This suggests that it is difficult to reduce the sheet resistance to about 800 (Q/□) and reduce the variation not only by ion implantation at a high energy but also ion implantation at a low energy.

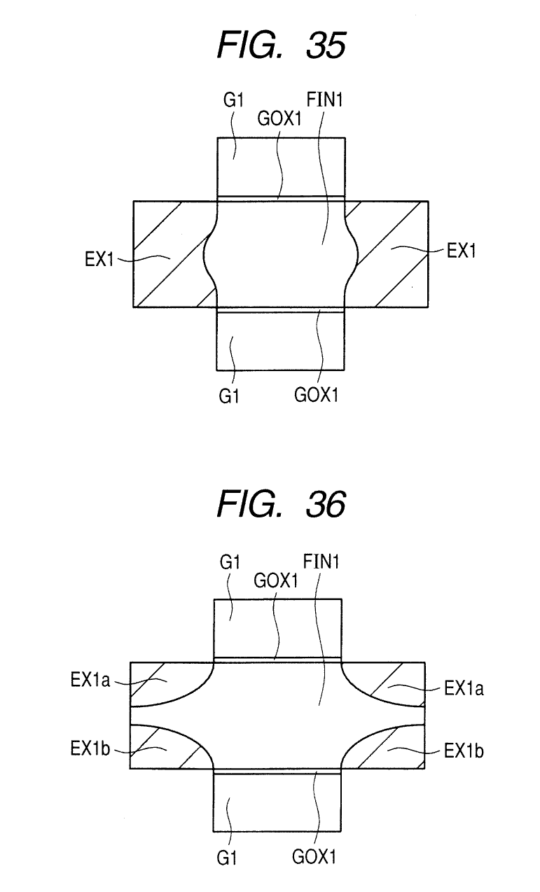

The behaviors shown by the curve (1) and the curve (2) in FIG. 34 will next be described qualitatively. First, the behavior when an impurity is implanted at a high energy as shown by the curve (1) will be described. FIG. 35 is a top view of the fin FIN1 implanted with an impurity at a high energy and the gate electrode G1 covering therewith the fin FIN1 is omitted from the diagram. In FIG. 35, an impurity is introduced into the fin FIN1 by using ion implantation to form a lightly-doped n-type impurity diffusion region EX1. The lightly-doped n-type impurity diffusion region EX1 illustrated in FIG. 35 is formed by introducing an impurity into the fin FIN1 at a high energy. In this case, an impurity is introduced from the side surface on both sides of the fin FIN1 by using oblique ion implantation. Since the energy upon ion implantation is high, the impurity is introduced into a deep portion of the fin FIN1. During ion implantation, the crystal structure of single crystal silicon configuring the fin FIN1 is destroyed due to the energy of an impurity and becomes amorphous. After introduction of an impurity, activation annealing is performed. Since the impurity has been introduced into a deep portion of the fin FIN1 as illustrated in FIG. 35, the region becomes amorphous. Even activation annealing is performed at this time, the single crystal silicon region is small so that silicon which has been introduced with an impurity and become amorphous cannot be returned to a single crystal state. It is therefore presumed that when an impurity is implanted at a high energy, scattering of electrons is amplified and the fin FIN1 has a high sheet resistance.

The behavior when an impurity is implanted at a low energy as shown by the curve (2) will be described. FIG. 36 is a top view of the fin FIN1 implanted with an impurity at a low energy and the gate electrode G1 covering therewith the fin FIN1 is omitted from the diagram. In FIG. 36, an impurity is introduced into the fin FIN1 by using ion implantation to form a lightly-doped n-type impurity diffusion region EX1a and a lightly-doped n-type impurity diffusion region EX1b. The lightly-doped n-type impurity diffusion regions EX1a and EX1b illustrated in FIG. 36 are formed by introducing an impurity into the fin FIN1 at a low energy. In this case, an impurity is introduced from the side surface on both sides of the fin FIN1 by using oblique ion implantation. Since the energy upon ion implantation is low, the impurity does not reach the deep portion of the fin FIN1. During ion implantation, the crystal structure of single crystal silicon configuring the fin FIN1 is destroyed due to the energy of the impurity and becomes amorphous. After introduction of the impurity, activation annealing is performed. As illustrated in FIG. 36, if there is a region not introduced with the impurity, it is in the form of single crystal silicon. When activation annealing is performed, with the single crystal silicon region as a seed crystal, silicon which has been introduced with an impurity and becomes amorphous can recover the single crystal state. When the silicon which has become amorphous recovers single crystal silicon, scattering of electrons is suppressed and increase in the resistance of the fin FIN1 can be suppressed. Based on the above findings, it is presumed that when ion implantation is performed at a low implantation energy, the sheet resistance can be decreased. Even if the implantation is performed at a low energy, when the dosage of the impurity is large, it is presumed that the impurity reaches even the deep portion of the fin FIN1 and seed crystals made of single crystal silicon decrease due to crystal recovery. As a result, even when the implantation is performed at a low energy, an increase in the dosage of an impurity causes a drastic increase in the sheet resistance, because crystal recovery cannot occur sufficiently. This means that it is difficult to actualize both a reduction in the sheet resistance to about 800 (Q/□) and also a reduction in the variation not only by ion implantation at a high energy but also by ion implantation at a low energy.

In Embodiment 2, as the method of introducing an impurity into the fin FIN1 not covered with the gate electrode G1, not ion implantation but a method using gas cluster ion beam (GCIB) is employed. This gas cluster ion beam is a mainly singly charged mass composed of from several hundreds to several tens of thousands of molecules. Compared with the conventional ion beam (one molecule is charged singly), an energy per molecule is very small so that it gives only a small damage to the surface of a solid upon collision thereto. In addition, gas cluster ion beam is characterized by that due to a sputtering (lateral sputtering) effect in the lateral direction or a lateral transfer effect of a substance upon collision, the surface of the solid can be planarized.

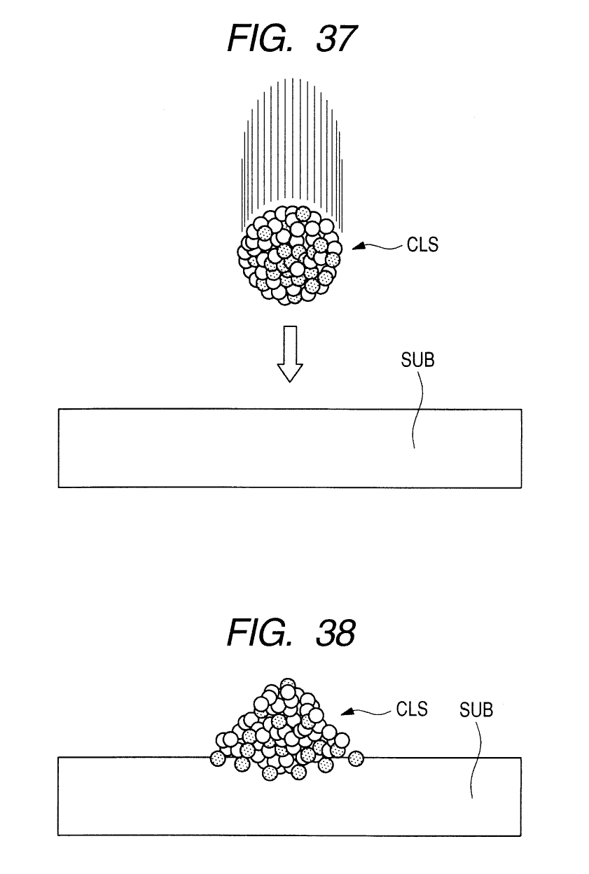

In the gas cluster ion beam, a cluster CLS which is a mass of from several hundreds to several tens of thousands of molecules is made to collide against a substrate SUB as illustrated in FIG. 37. Upon collision, the cluster CLS contains an impurity to be introduced into the substrate SUB. The cluster CLS collides against the substrate SUB as illustrated in FIG. 38. Since an energy per molecule is very small, damage given to the surface of a solid upon collision can be decreased. Heat treatment is thereafter conducted to diffuse the impurity in the substrate SUB.

The damage of the fin FIN1 can be decreased by using gas cluster ion beam for introducing an impurity into the fin FIN1 not covered with the gate electrode G1. In other words, even if the dosage of an impurity is increased, it is possible to prevent the fin FIN1 from becoming amorphous due to the damage and at the same time, to sufficiently effect the recovery to single crystal silicon. Using a gas cluster ion beam technology makes it possible, for example, to reduce the sheet resistance of a FINFET to about 800 (Q/□) and at the same time, reduce the variation in sheet resistance.

The invention made by the present inventors has been described specifically based on some embodiments. It is needless to say that the invention is not limited to or by these embodiments and various modifications and alterations can be made without departing from the scope of the present invention.

The present invention can be used widely in the manufacturers of semiconductor devices.

What is claimed is:

1. A semiconductor device comprising a first MISFET formed in a first region, the first MISFET including:
(a) an SOI substrate having a substrate layer, a buried insulating layer formed over the substrate layer, and a semiconductor layer formed over the buried insulating layer;
(b) a fin in a rectangular solid form with a long side in a first direction formed by processing the semiconductor layer;
(c) a first source region formed by processing the semiconductor layer and coupled to one end of the fin;
(d) a first drain region formed by processing the semiconductor layer and coupled to another end of the fin;
(e) a first gate insulating film formed over the surface of the fin; and
(f) a first gate electrode straddling over the surface of the fin via the first gate insulating film in a region extending in a second direction intersecting with the first direction and intersecting with the fin,
wherein a first semiconductor region having a conductivity type impurity introduced therein is formed in a portion of the substrate layer contiguous to the buried insulating layer, and
wherein a ratio of the height of the fin to the width of the fin, which is a width in the second direction, is 1 or greater but not greater than 2.

2. The semiconductor device according to claim 1,
wherein the first MISFET is an n channel MISFET.

3. The semiconductor device according to claim 2,
wherein the conductivity type impurity introduced into the first semiconductor region is an n type impurity.

4. The semiconductor device according to claim 1,
wherein the first MISFET is a p channel MISFET.

5. The semiconductor device according to claim 4,
wherein the conductivity type impurity introduced into the first semiconductor region is a p type impurity.

6. The semiconductor device according to claim 1,
wherein the thickness of the buried insulating layer is 10 nm or greater but not greater than 20 nm.

7. The semiconductor device according to claim 1,
wherein a voltage is applied to the first semiconductor region.

8. The semiconductor device according to claim 7,
wherein an absolute value of the voltage applied to the first semiconductor region is within an absolute value of a supply voltage for actuating the first MISFET.

9. The semiconductor device according to claim 7,
wherein the voltage applied to the first semiconductor region is within a range of from −1V to 1V.

10. The semiconductor device according to claim 1, further comprising:
a second MISFET formed in a second region, the second MISFET including:
(g) a second gate insulating film formed over the substrate layer;
(h) a second gate electrode formed over the second gate insulating film;
(i) a second source region formed in the substrate layer; and
(j) a second drain region formed in the substrate layer.

11. The semiconductor device according to claim 10,
wherein the first MISFET is a MISFET configuring a SRAM or a logic circuit and the second MISFET is a MISFET configuring an input/output circuit.

12. A manufacturing method of a semiconductor device comprising the steps of:
(a) preparing a SOI substrate having a substrate layer, a buried insulating layer formed over the substrate layer, and a semiconductor layer formed over the buried insulating layer;
(b) introducing a conductivity type impurity into the substrate layer of the SOI substrate, thereby forming in the substrate layer a first semiconductor region contiguous to the buried insulating layer; and
(c) forming a first MISFET in a first region of the SOI substrate,
wherein the step (c) comprises the steps of:
(c1) processing the semiconductor layer of the SOI substrate to form a fin in a rectangular solid form with a long side in a first direction, a first source region to be coupled to one end of the fin, and a first drain region to be coupled to another end of the fin;
(c2) forming a first gate insulating film over the surface of the fin;
(c3) forming, over the SOI substrate having the fin formed thereon, a first conductor film covering the fin therewith;
(c4) processing the first conductor film to form a first gate electrode that straddles over the surface of the fin via the first gate insulating film in a region extending in a second direction intersecting with the first direction and at the same time intersecting with the fin; and
(c5) introducing a conductivity type impurity into the first source region and the first drain region,
wherein a ratio of the height of the fin formed in the step (c) to the width of the fin, which is a width in the second direction of the fin is 1 or greater but not greater than 2.

13. The manufacturing method of a semiconductor device according to claim 12,
wherein the buried insulating layer of the SOI substrate has a thickness of from 10 nm or greater but not greater than 20 nm.

14. The manufacturing method of a semiconductor device according to claim 12,
wherein the first MISFET is an n-channel MISFET, and
wherein an n type impurity is introduced into the first semiconductor region formed in the step (b).

15. The manufacturing method of a semiconductor device according to claim 12,
wherein the first MISFET is a p channel MISFET, and
wherein a p type impurity is introduced into the first semiconductor region formed in the step (b).

16. The manufacturing method of a semiconductor device according to claim 12,
wherein the step (c5) comprises the steps of:
(c5-1) after formation of the first gate electrode in the step (c4), introducing a conductivity type impurity into a portion of the fin, the first source region, and the first drain region exposed without being covered with the first gate electrode;
(c5-2) after the step (c5-1), forming a sidewall over the side surfaces of the first gate electrode; and
(c5-3) after the step (c5-2), introducing a conductivity type impurity into a portion of the fin, the first source region, and the first drain region exposed without being covered with the sidewall.

17. The manufacturing method of a semiconductor device according to claim 16,
wherein the step (c5-1) is performed by using gas cluster ion beam to introduce the conductivity type impurity into the portion of the fin, the first source region, and the first drain region exposed without being covered with the first gate electrode and then heating the SOI substrate to diffuse the conductivity type impurity thus introduced.

18. A manufacturing method of a semiconductor device having a first MISFET in a first region and a second MISFET in a second region, comprising the steps of:
(a) preparing a SOI substrate having a substrate layer, a buried insulating layer formed over the substrate layer, and a semiconductor layer formed over the buried insulating layer;
(b) removing the semiconductor layer and the buried insulating layer formed in the second region of the SOI substrate to expose the substrate layer;
(c) introducing a conductivity type impurity into the substrate layer formed in the first region of the SOI substrate to form a first semiconductor region contiguous to the buried insulating layer in the substrate layer formed in the first region; and
(d) forming the first MISFET in the first region and forming the second MISFET in the second region,
wherein the step (d) comprises the steps of:
(d1) processing the semiconductor layer of the SOI substrate in the first region to form a fin in a rectangular solid form with a long side in a first direction, a first source region to be coupled to one end of the fin, and a first drain region to be coupled to another end of the fin;
(d2) forming a first gate insulating film over the surface of the fin formed in the first region and forming a second gate insulating film over the substrate layer formed in the second region;
(d3) forming a first conductor film over the SOI substrate having the fin formed thereover so as to cover the fin in the first region, while forming the first conductor film over the second gate insulating film in the second region;
(d4) processing the first conductor film formed in the first region to form a first gate electrode straddling over the surface of the fin via the first gate insulating film in a region extending in a second direction intersecting with the first direction and at the same time, intersecting with the fin, while processing the first conductor film formed in the second region to form a second gate electrode over the second gate insulating film;
(d5) introducing a conductivity type impurity into the first source region and the first drain region formed in the first region; and
(d6) introducing a conductivity type impurity into the substrate layer formed in the second region to form a second source region and a second drain region,
wherein a ratio of the height of the fin formed in the step (d1) to the width of the fin, which is a width in the second direction, is 1 or greater but not greater than 2.

19. The manufacturing method of a semiconductor device according to claim 18,
wherein the step (d5) is performed by using gas cluster ion beam to introduce the conductivity type impurity into a portion of the fin, the first source region, and the first drain region exposed without being covered with the first gate electrode and then heating the SOI substrate to diffuse the conductivity type impurity thus introduced.
